(19) United States
(12) Patent Application Publication
(10) Pub. No.: US 2022/0075267 A1
(43) Pub. Date: Mar. 10, 2022

(54) FILM-FORMING COMPOSITION, RESIST UNDERLAYER FILM, METHOD OF FORMING FILM, METHOD OF FORMING RESIST PATTERN, METHOD OF FORMING ORGANIC-UNDERLAYER-FILM REVERSE PATTERN, METHOD OF PRODUCING FILM-FORMING COMPOSITION, AND METHOD OF FORMING METAL-CONTAINING FILM PATTERN

(71) Applicant: JSR CORPORATION, Tokyo (JP)

(72) Inventors: Yuusuke OOTSUBO, Tokyo (JP); Ryuichi SERIZAWA, Tokyo (JP); Yuuki OZAKI, Tokyo (JP); Kazunori SAKAI, Tokyo (JP)

(73) Assignee: JSR CORPORATION, Tokyo (JP)

(21) Appl. No.: 17/528,373

(22) Filed: Nov. 17, 2021

Related U.S. Application Data
(63) Continuation of application No. PCT/JP2020/020989, filed on May 27, 2020.

(30) Foreign Application Priority Data
May 30, 2019 (JP) 2019-101806
Feb. 4, 2020 (JP) 2020-016988

(51) Int. Cl. G03F 7/11; G03F 7/20; G03F 7/32

(52) U.S. Cl. CPC G03F 7/11; G03F 7/32; G03F 7/2004

(57) ABSTRACT

A film-forming composition includes: a metal compound; a nitrogen-containing organic compound; and a solvent. The nitrogen-containing organic compound is: a first compound including a nitrogen atom, an aliphatic hydrocarbon group, and at least two hydroxy groups; a second compound including a nitrogen-containing aromatic heterocycle and at least one hydroxy group; or a mixture thereof. A method of forming a resist pattern includes applying the film-forming composition directly or indirectly on a substrate to form a resist underlayer film. An organic-resist-film-forming composition is applied directly or indirectly on the resist underlayer film to form an organic resist film. The organic resist film is exposed to a radioactive ray. The organic resist film exposed is developed.

### CROSS-REFERENCE TO RELATED APPLICATIONS

The present application is a continuation application of International Application No. PCT/JP2020/020989, filed May 27, 2020, which claims priority to Japanese Patent Application No. 2019-101806, filed May 30, 2019, and to Japanese Patent Application No. 2020-016988, filed Feb. 4, 2020. The contents of these applications are incorporated herein by reference in their entirety.

### BACKGROUND OF THE INVENTION

### Field of the Invention

The present invention relates to a film-forming composition, a resist underlayer film, a method of forming a film, a method of forming a resist pattern, a method of forming an organic-underlayer-film reverse pattern, a method of producing a film-forming composition, and a method of forming a metal-containing film pattern.

### Description of the Related Art

In manufacturing elements for semiconductors and the like, using a hydrolytic condensation product of a metal alkoxide has been proposed (see Japanese Unexamined Patent Application, Publication No. 2014-134592).

### SUMMARY OF THE INVENTION

According to an aspect of the present invention, a film-forming composition includes: a metal compound; a nitrogen-containing organic compound; and a solvent. The nitrogen-containing organic compound is: a first compound including a nitrogen atom, an aliphatic hydrocarbon group, and at least two hydroxy groups; a second compound including a nitrogen-containing aromatic heterocycle and at least one hydroxy group; or a mixture thereof.

According to another aspect of the present invention, a resist underlayer film is formed from the above-mentioned film-forming composition.

According to a further aspect of the present invention, a method of forming a film includes applying the above-mentioned film-forming composition directly or indirectly on a substrate.

According to a further aspect of the present invention, a method of forming a resist pattern includes applying the above-mentioned film-forming composition directly or indirectly on a substrate to form a resist underlayer film. An organic-resist-film-forming composition is applied directly or indirectly on the resist underlayer film to form an organic resist film. The organic resist film is exposed to a radioactive ray. The organic resist film exposed is developed.

According to a further aspect of the present invention, a method of forming an organic-underlayer-film reverse pattern includes forming an organic underlayer film directly or indirectly on a substrate. A resist pattern is formed directly or indirectly on the organic underlayer film. An organic-underlayer-film pattern is formed on the organic underlayer film by carrying out etching using the resist pattern as a mask. An organic-underlayer-film-reverse-pattern-forming film is formed directly on the organic-underlayer-film pattern by applying an organic-underlayer-film-reverse-pattern-forming composition. An organic-underlayer-film reverse pattern is formed by removing the organic-underlayer-film pattern. The organic-underlayer-film-reverse-pattern-forming composition includes: a metal compound; a nitrogen-containing organic compound; and a solvent. The nitrogen-containing organic compound is: a first compound including a nitrogen atom, an aliphatic hydrocarbon group, and at least two hydroxy groups; a second compound including a nitrogen-containing aromatic heterocycle and at least one hydroxy group; or a mixture thereof.

According to a further aspect of the present invention, a method of producing a film-forming composition includes: mixing a metal alkoxide with a nitrogen-containing organic compound to obtain a mixture; and adding water to the mixture. The nitrogen-containing organic compound is: a first compound including a nitrogen atom, an aliphatic hydrocarbon group, and at least two hydroxy groups; a second compound including a nitrogen-containing aromatic heterocycle and at least one hydroxy group; or a mixture thereof.

According to a further aspect of the present invention, a method of forming a metal-containing film pattern includes applying a metal-containing-film-forming composition directly or indirectly on a substrate. An organic underlayer film is formed directly or indirectly on a metal-containing film formed by applying the metal-containing-film-forming composition. A resist pattern is formed directly or indirectly on the organic underlayer film. A pattern is formed on the metal-containing film by carrying out etching using the resist pattern as a mask. The metal-containing-film-forming composition is the above-mentioned film-forming composition.

### DESCRIPTION OF EMBODIMENTS

One embodiment of the invention is a film-forming composition (hereinafter, may be also referred to as “composition (J)”) containing: a metal compound (hereinafter, may be also referred to as “(A) compound” or “compound (A)”); a nitrogen-containing organic compound (hereinafter, may be also referred to as “(X) compound” or “compound (X)”); and a solvent (hereinafter, may be also referred to as “(C) solvent” or “solvent (C)”), wherein the compound (X) is: a compound (hereinafter, may be also referred to as “(X1) compound” or “compound (X1)”) having a nitrogen atom, an aliphatic hydrocarbon group, and at least two hydroxy groups; a compound (hereinafter, may be also referred to as “(X2) compound” or “compound (X2)”) having a nitrogen-containing aromatic heterocycle and at least one hydroxy group; or a mixture of these.

Another embodiment of the invention is a resist underlayer film formed from a film-forming composition, wherein the film-forming composition contains a metal compound (compound (A)), a nitrogen-containing organic compound (compound (X)), and a solvent (solvent (C)), wherein the compound (X) is: a compound (compound (X1)) having a nitrogen atom, an aliphatic hydrocarbon group, and at least two hydroxy groups; a compound (compound (X2)) having a nitrogen-containing aromatic heterocycle and at least one hydroxy group; or a mixture of these.

A still another embodiment of the invention is a method of forming a film, the method including applying a film-forming composition directly or indirectly on a substrate, wherein the film-forming composition contains a metal compound (compound (A)), a nitrogen-containing organic compound (compound (X)), and a solvent (solvent (C)), wherein the compound (X) is: a compound (compound (X1)) having a nitrogen atom, an aliphatic hydrocarbon group, and at least two hydroxy groups; a compound (compound (X2)) having a nitrogen-containing aromatic heterocycle and at least one hydroxy group; or a mixture of these.

A yet another embodiment of the invention is a method of forming a resist pattern, the method including: applying a film-forming composition directly or indirectly on a substrate; applying an organic-resist-film-forming composition directly or indirectly on a resist underlayer film formed by the applying of the film-forming composition; exposing to a radioactive ray, an organic resist film formed by the applying of the organic-resist-film-forming composition; and developing the organic resist film exposed, wherein the film-forming composition contains: a metal compound (compound (A)); a nitrogen-containing organic compound (compound (X)); and a solvent (solvent (C)), wherein the compound (X) is a compound (compound (X1)) having a nitrogen atom, an aliphatic hydrocarbon group, and at least two hydroxy groups; a compound (compound (X2)) having a nitrogen-containing aromatic heterocycle and at least one hydroxy group; or a mixture of these.

A further embodiment of the invention is a method of forming an organic-underlayer-film reverse pattern, the method including: forming an organic underlayer film directly or indirectly on a substrate; forming a resist pattern directly or indirectly on the organic underlayer film; forming a pattern on the organic underlayer film by carrying out etching using the resist pattern as a mask; forming an organic-underlayer-film-reverse-pattern-forming film directly on the organic-underlayer-film pattern by using an organic-underlayer-film-reverse-pattern-forming composition; and forming an organic-underlayer-film reverse pattern by removing the organic-underlayer-film pattern, wherein the organic-underlayer-film-reverse-pattern-forming composition contains: a metal compound (compound (A)); a nitrogen-containing organic compound (compound (X)); and a solvent (solvent (C)), wherein the compound (X) is: a compound (compound (X1)) having a nitrogen atom, an aliphatic hydrocarbon group, and at least two hydroxy groups; a compound (compound (X2)) having a nitrogen-containing aromatic heterocycle and at least one hydroxy group; or a mixture of these.

A yet further embodiment of the invention is a method of producing a film-forming composition, the method including: mixing a metal alkoxide and a nitrogen-containing organic compound (compound (X)); and adding water to a mixture obtained by the mixing, wherein the compound (X) is: a compound (compound (X1)) having a nitrogen atom, an aliphatic hydrocarbon group, and at least two hydroxy groups; a compound (compound (X2)) having a nitrogen-containing aromatic heterocycle and at least one hydroxy group; or a mixture of these.

A still further embodiment of the invention is a method of forming a metal-containing film pattern, the method including: applying a metal-containing-film-forming composition directly or indirectly on a substrate; forming an organic underlayer film directly or indirectly on a metal-containing film formed by applying the metal-containing-film-forming composition; forming a resist pattern directly or indirectly on the organic underlayer film; and forming a pattern on the metal-containing film by carrying out etching using the resist pattern as a mask, wherein the metal-containing-film-forming composition contains: a metal compound (compound (A)); a nitrogen-containing organic compound (compound (X)); and a solvent (solvent (C)), wherein the compound (X) is: a compound (compound (X1)) having a nitrogen atom, an aliphatic hydrocarbon group, and at least two hydroxy groups; a compound (compound (X2)) having a nitrogen-containing aromatic heterocycle and at least one hydroxy group; or a mixture of these.

The film-forming composition of the one embodiment of the present invention is superior in storage stability and the embedding property.

Moreover, the film-forming composition of the one embodiment of the present invention enables forming a film being superior in each of a film-thickness-variation-inhibiting property, etching resistance, and removability. Since the resist underlayer film of the other embodiment of the present invention is formed from the film-forming composition of the one embodiment of the present invention, superiority is achieved in the film-thickness-variation-inhibiting property, etching resistance, and removability. The method of forming a film of the still another embodiment of the present invention enables forming a film being superior in each of the film-thickness-variation-inhibiting property, etching resistance, and removability. Since the method of forming a resist pattern of the still another embodiment of the present invention uses the film-forming composition of the one embodiment of the present invention, a favorable resist pattern can be formed. Since the method of forming an organic-underlayer-film reverse pattern of the further embodiment of the present invention uses the film-forming composition of the one embodiment of the present invention as an organic-underlayer-film-reverse-pattern-forming composition, a favorable reverse pattern can be formed. The method of producing a film-forming composition of the yet further embodiment of the present invention enables producing a film-forming composition being superior in storage stability and the embedding property.

Since the method of forming a metal-containing film pattern of the still further embodiment of the present invention uses the film-forming composition of the one embodiment of the present invention as a metal-containing-film-forming composition, a favorable metal-containing film pattern can be formed.

Therefore, these can be suitably used in lithography steps in production of various types of electronic devices such as semiconductor devices and liquid crystal devices, for which there is a demand for further microfabrication, and the like.

The present inventors sensed a need in which there was a requirement for a film-forming composition which enables forming, for example, a thick film of no less than 50 nm as a metal-containing film. However, the present inventors newly found that the film-forming composition which uses the conventional hydrolytic condensation product of a metal alkoxide involves the following problems: coating characteristics are unfavorable when forming a thick film; and in the case of forming the thick film, cracks are generated in the film.

As a result of intensive studies to solve the aforementioned problems, the present inventors discovered that surprisingly, according to the film-forming composition of one embodiment of the present invention: the coating characteristics when forming a thick film are favorable, and further, even in the case in which the thick film has been formed, inhibiting the generation of cracks in the film is enabled.

Thus, the film-forming composition of one embodiment of the present invention is superior in coating characteristics when forming a thick film. Moreover, the film-forming composition of the one embodiment of the present invention enables forming a thick film in which the generation of cracks is inhibited. It is to be noted that as referred to herein, “thick film” means a film having an average thickness of no less than 50 nm. It is also to be noted that the average thickness is a value measured using a spectroscopic ellipsometer (“A2000D,” available from J.A. Woollam Co.).

Furthermore, according to a method of forming a metal-containing film pattern of a still further embodiment of the present invention, using the film-forming composition of the one embodiment of the present invention as the metal-containing-film-forming composition enables forming the thick film in which the generation of cracks is inhibited, thereby enabling forming a favorable metal-containing film pattern.

### Composition (J)

The composition (J) contains the compound (A), the compound (X), and the solvent (C). The composition (J) may contain other optional component(s) within a range not leading to impairment of the effects of the present invention.

Due to containing the compound (A), the compound (X), and the solvent (C), the composition (J) is superior in storage stability and the embedding property. Although not necessarily clarified and without wishing to be bound by any theory, the reason for achieving the aforementioned effects by the composition (J) due to involving such a constitution may be presumed, for example, as in the following. It is considered that coordination of the nitrogen atom and the hydroxy groups of the compound (X) to a metal atom of the compound (A), or the presence of the nitrogen atom and the hydroxy groups around the metal atom of the compound (A) enables enhancing flowability during application, and it is believed that as a result, the embedding property of the composition (J) is improved. In addition, it is considered that coordination of the nitrogen atom and the hydroxy groups of the compound (X) to a metal atom of the compound (A), or the presence of the nitrogen atom and the hydroxy groups around the metal atom of the compound (A) enables inhibiting deterioration of the compound (A) over time, and it is believed that as a result, the storage stability of the composition (J) is improved.

Furthermore, the film formed from the composition (J) is superior in the film-thickness-variation-inhibiting property, etching resistance, and removability. Although not necessarily clarified and without wishing to be bound by any theory, the reason for achieving the aforementioned effects by the film formed from the composition (J) may be presumed, for example, as in the following. It is considered that coordination of the nitrogen atom and the hydroxy groups of the compound (X) to a metal atom of the compound (A), or the presence of the nitrogen atom and the hydroxy groups around the metal atom of the compound (A) enhances the etching resistance and removability of the film formed from the composition (J). In addition, it is considered that the nitrogen atom and the hydroxy groups of the compound (X) being coordinated to the metal atom of the compound (A), or present in the perimeter of the metal atom of the compound (A) enable inhibiting deterioration of the compound (A) over time, and it is believed that as a result, the film-thickness-variation-inhibiting property of the film formed from the composition (J) is improved.

Furthermore, the composition (J) is superior in coating characteristics when forming the thick film. The reason for achieving the aforementioned effect is considered to be because coordination of the nitrogen atom and the hydroxy groups of the compound (X) to a metal atom of the compound (A), or the presence of the nitrogen atom and the hydroxy groups around the metal atom enables enhancing flowability at the time of application. In addition, the film formed from the composition (J) enables inhibiting the occurrence of cracks, even in the case of the thick film. The reason for achieving the aforementioned effect is considered to be that due to coordination of the nitrogen atom and the hydroxy groups of the compound (X) to a metal atom of the compound (A), or the presence of the nitrogen atom and the hydroxy groups around the metal atom, the variation in the film can be inhibited in a case of heating the film, and it is believed that as a result, inhibiting the generation of cracks is enabled.

Each component contained in the composition (J) will be described below.

(A) Compound

The compound (A) is a metal alkoxide (hereinafter, may be also referred to as “(M) compound” or “compound (M)”), a hydrolytic condensation product of the compound (M), or a mixture of these. The “hydrolytic condensation” as referred to herein means a reaction in which an alkoxide group contained in the compound (M) is hydrolyzed to give —OH, and two —OHs thus obtained undergo dehydrative condensation to eliminate one water molecule, thereby forming an “—O—” bond. The composition (J) may contain one, or two or more types of the compound (A).

In the composition (J), the compound (X) may be coordinated to the metal atom (hereinafter, may be also referred to as “metal atom (L)”) contained in the compound (A), and/or may be free from the metal atom (L) contained in the compound (A). Specifically, for example, a part of the compound (X) may be coordinated to the metal atom (L) in the compound (A), with the remainder of the compound (X) being free from the metal atom (L) in the compound (A). In the case in which the compound (X) is coordinated to the metal atom (L) in the compound (A), the compound (X) may be coordinated to the metal atom (L) as either a monodentate ligand or a polydentate ligand.

The metal atom (L) contained in the compound (A) is exemplified by an atom belonging to period 3 to period 7 of group 2 to group 14 in the periodic table.

Examples of the metal atom (L) belonging to group 2 include a magnesium atom, a calcium atom, a strontium atom, a barium atom, and the like;

examples of the metal atom (L) belonging to group 3 include atoms belonging to lanthanoids such as a scandium atom, an yttrium atom, and a lanthanum atom; atoms belonging to actinoids such as an actinium atom; and the like;

examples of the metal atom (L) belonging to group 4 include a titanium atom, a zirconium atom, a hafnium atom, and the like;

examples of the metal atom (L) belonging to group 5 include a vanadium atom, a niobium atom, a tantalum atom, and the like;

examples of the metal atom (L) belonging to group 6 include a chromium atom, a molybdenum atom, a tungsten atom, and the like;

examples of the metal atom (L) belonging to group 7 include a manganese atom, a rhenium atom, and the like;

examples of the metal atom (L) belonging to group 8 include an iron atom, a ruthenium atom, an osmium atom, and the like;

examples of the metal atom (L) belonging to group 9 include a cobalt atom, a rhodium atom, an iridium atom, and the like;

examples of the metal atom (L) belonging to group 10 include a nickel atom, a palladium atom, a platinum atom, and the like;

examples of the metal atom (L) belonging to group 11 include a copper atom, a silver atom, a gold atom, and the like;

examples of the metal atom (L) belonging to group 12 include a zinc atom, a cadmium atom, a mercury atom, and the like;

examples of the metal atom (L) belonging to group 13 include an aluminum atom, a gallium atom, an indium atom, a thallium atom, and the like; and

examples of the metal atom (L) belonging to group 14 include a tin atom, a lead atom, and the like.

The compound (A) may have one, or two or more types of the metal atom (L). Furthermore, the compound (M) may have one, or two or more types of the metal atom (L).

Of these, the metal atom (L) is preferably the atom belonging to group 3, group 4, or group 13 of the periodic table, and more preferably the atom belonging to group 4 of the periodic table.

The alkoxide group contained in the compound (M) is exemplified by a methoxy group, an ethoxy group, an n-propoxy group, an i-propoxy group, a butoxy group, and the like.

Examples of the compound (M) include:

titanium-containing compounds such as diisopropoxybis(2,4-pentanedionato) titanium(IV), tetra-n-butoxy titanium(IV), tetra-n-propoxy titanium(IV), tetraisopropoxy titanium(IV), tri-n-butoxymonostearate titanium(IV), a titanium(IV) butoxide oligomer, aminopropyltrimethoxy titanium(IV), triethoxymono(2,4-pentanedionato) titanium(IV), tri-n-propoxymono(2,4-pentanedionato) titanium(IV), triisopropoxymono(2,4-pentanedionato) titanium, and di-n-butoxybis(2,4-pentanedionato) titanium(IV);

zirconium-containing compounds such as dibutoxybis(ethylacetoacetate) zirconium(IV), di-n-butoxybis(2,4-pentanedionato) zirconium(IV), tetra-n-butoxy zirconium(IV), tetra-n-propoxy zirconium(IV), tetraisopropoxy zirconium(IV), aminopropyltriethoxy zirconium(IV), 2-(3,4-epoxycyclohexyl)ethyltrimethoxy zirconium(IV), γ-glycidoxypropyltrimethoxy zirconium(IV), 3-isocyanopropyltrimethoxy zirconium(IV), triethoxymono(2,4-pentanedionato) zirconium(IV), tri-n-propoxymono(2,4-pentanedionato) zirconium(IV), triisopropoxymono(2,4-pentanedionato) zirconium(IV), tri(3-methacryloxypropyl)methoxy zirconium(IV), and tri(3-acryloxypropyl)methoxy zirconium(IV);

hafnium-containing compounds such as diisopropoxybis(2,4-pentanedionato) hafnium(IV), tetrabutoxy hafnium(IV), tetraisopropoxy hafnium(IV), tetraethoxy hafnium(IV), and dichlorobis(cyclopentadienyl) hafnium(IV);

tantalum-containing compounds such as tetrabutoxy tantalum(IV), pentabutoxy tantalum(V), and pentaethoxy tantalum(V);

tungsten-containing compounds such as tetrabutoxy tungsten(IV), pentabutoxy tungsten(V), pentamethoxy tungsten(V), hexabutoxy tungsten(VI), hexaethoxy tungsten(VI), and dichlorobis(cyclopentadienyl) tungsten(IV);

iron-containing compounds such as iron chloride(III);

ruthenium-containing compounds such as diacetato[(S)-(−)-2,2′-bis(diphenylphosphino)-1,1′-binaphthyl] ruthenium(II);

cobalt-containing compounds such as dichloro[ethylenebis(diphenylphosphine)] cobalt(II);

zinc-containing compounds such as diisopropoxy zinc(II) and zinc(II) acetate;

aluminum-containing compounds such as triisopropoxy aluminum (III), diisopropoxyethylacetoacetate aluminum(III), and aluminum(III) acetate;

indium-containing compounds such as indium(III) acetate and triisopropoxy indium(III);

tin-containing compounds such as tetraethyldiacetoxy stannoxane, tetrabutoxy tin(IV), tetraisopropoxy tin(IV), and t-butyltris(diethylamide) tin(IV); and

germanium-containing compounds such as tetraisopropoxy germanium(IV).

The lower limit of a proportion of the compound (A) with respect to total components contained in the composition (J) is preferably 2% by mass, more preferably 4% by mass, and still more preferably 6% by mass. The upper limit of the proportion in the composition (J) is preferably 20% by mass, more preferably 15% by mass, and still more preferably 10% by mass.

(X) Compound

The compound (X) is the compound (X1), the compound (X2), or a mixture of these. The composition (J) may contain one, or two or more types of the compound (X).

(X1) Compound

The compound (X1) is a compound having a nitrogen atom, an aliphatic hydrocarbon group, and at least two hydroxy groups.

The compound (X1) has at least one nitrogen atom. The number of nitrogen atom(s) in the compound (X1) is preferably 1 to 10, more preferably 1 to 7, and still more preferably 2 to 5. Furthermore, in the compound (X1), the nitrogen atom(s) is/are preferably bonded to the carbon atom in the aliphatic hydrocarbon group.

The compound (X1) has at least one aliphatic hydrocarbon group. The number of aliphatic hydrocarbon group(s) in the compound (X1) is preferably 2 to 10, more preferably 2 to 7, and still more preferably 2 to 5. The compound (X1) preferably has the aliphatic hydrocarbon group(s) bonded to the nitrogen atom(s) and the hydroxy groups (in other words, each present between the nitrogen atom and the hydroxy group). In addition, in the case in which the compound (X1) has at least two nitrogen atoms, the aliphatic hydrocarbon group(s) is/are preferably bonded between the nitrogen atoms (in other words, present between the at least two nitrogen atoms). Such an aliphatic hydrocarbon group may be exemplified by a divalent aliphatic hydrocarbon group having 1 to 10 carbon atoms.

The “aliphatic hydrocarbon group” as referred to herein may be exemplified by a chain hydrocarbon group and an alicyclic hydrocarbon group. The “hydrocarbon group” may be either a saturated hydrocarbon group or an unsaturated hydrocarbon group. The “chain hydrocarbon group” as referred to herein means a hydrocarbon group not including a cyclic structure but being constituted with only a chain structure, and may be exemplified by both a linear hydrocarbon group and a branched hydrocarbon group. The “alicyclic hydrocarbon group” as referred to herein means a hydrocarbon group that includes, as a ring structure, not an aromatic ring structure but an alicyclic structure alone, and may be exemplified by both a monocyclic alicyclic hydrocarbon group and a polycyclic alicyclic hydrocarbon group. With regard to this, it is not necessary for the alicyclic hydrocarbon group to be constituted with only an alicyclic structure; it may include a chain structure in a part thereof.

Examples of the divalent chain hydrocarbon group having 1 to 10 carbon atoms include:

alkanediyl groups such as a methanediyl group, an ethanediyl group, an n-propanediyl group, an i-propanediyl group, an n-butanediyl group, an i-butanediyl group, a sec-butanediyl group, and a t-butanediyl group;

alkenediyl groups such as an ethenediyl group, a propenediyl group, and a butenediyl group;

alkynediyl groups such as an ethynediyl group, a propynediyl group, and a butynediyl group; and the like.

Examples of the divalent alicyclic hydrocarbon group having 3 to 10 carbon atoms include:

monocyclic cycloalkanediyl groups such as a cyclopropanediyl group, a cyclobutanediyl group, a cyclopentanediyl group, and a cyclohexanediyl group;

monocyclic cycloalkenediyl groups such as a cyclopropenediyl group, a cyclobutenediyl group, a cyclopentenediyl group, and a cyclohexenediyl group;

polycyclic cycloalkanediyl groups such as a norbornanediyl group, an adamantanediyl group, and a tricyclodecanediyl group;

polycyclic cycloalkenediyl groups such as a norbornenediyl group and a tricyclodecenediyl group; and the like.

The upper limit of the number of carbon atoms in the divalent aliphatic hydrocarbon group is preferably 10, more preferably 6, and still more preferably 4. The lower limit of the number of carbon atoms is, for example, 1.

The compound (X1) has at least two hydroxy groups. As described above, the hydroxy groups are preferably bonded to the aliphatic hydrocarbon group(s). The number of hydroxy groups in the compound (X1) is preferably 2 to 10, more preferably 2 to 7, and still more preferably 2 to 5.

Examples of the compound (X1) include compounds represented by the following formula (1), and the like.

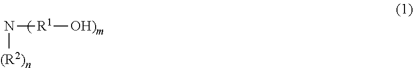

In the above formula (1), (m+n) is 3, m is 2 or 3, and n is 0 or 1; R¹ represents a divalent aliphatic hydrocarbon group having 1 to 10 carbon atoms, wherein a plurality of R¹s are identical or different; and R² represents a hydrogen atom, a monovalent aliphatic hydrocarbon group having 1 to 10 carbon atoms, or a group represented by the following formula (1-1).

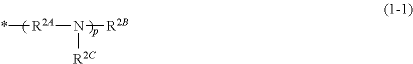

In the above formula (1-1), R^{2A} represents a divalent aliphatic hydrocarbon group having 1 to 10 carbon atoms; R^{2B} and R^{2C} each independently represent a hydrogen atom, a monovalent aliphatic hydrocarbon group having 1 to 10 carbon atoms, or —R^{2D}—OH, wherein R^{2D} represents a divalent aliphatic hydrocarbon group having 1 to 10 carbon atoms; p is an integer of 1 to 4, wherein in a case in which p is no less than 2, a plurality of R^{2A}s are identical or different from each other, and a plurality of R^{2C}s are identical or different from each other; and * denotes a site bonding to the nitrogen atom in the above formula (1).

The divalent aliphatic hydrocarbon group having 1 to 10 carbon atoms which is represented by R^{2A} may be exemplified by the groups exemplified as the divalent aliphatic hydrocarbon group, which has been exemplified as the aliphatic hydrocarbon group contained in the compound (X1) described above, and the like.

The monovalent aliphatic hydrocarbon group having 1 to 10 carbon atoms which may be represented by R²¹ or R^{2C} is exemplified by a monovalent chain hydrocarbon group having 1 to 10 carbon atoms, a monovalent alicyclic hydrocarbon group having 3 to 10 carbon atoms, and the like.

Examples of the monovalent chain hydrocarbon group having 1 to 10 carbon atoms include:

alkyl groups such as a methyl group, an ethyl group, an n-propyl group, an i-propyl group, an n-butyl group, an i-butyl group, a sec-butyl group, and a t-butyl group;

alkenyl groups such as an ethenyl group, a propenyl group, and a butenyl group; alkynyl groups such as an ethynyl group, a propynyl group, and a butynyl group; and the like.

Examples of the monovalent alicyclic hydrocarbon group having 3 to 10 carbon atoms include:

monocyclic cycloalkyl groups such as a cyclopropyl group, a cyclobutyl group, a cyclopentyl group, a cyclohexyl group, and a cyclooctyl group;

polycyclic cycloalkyl groups such as a norbornyl group, an adamantyl group, and a tricyclodecyl group;

monocyclic cycloalkenyl groups such as a cyclobutenyl group, a cyclopentenyl group, and a cyclohexenyl group;

polycyclic cycloalkenyl group such as a norbornenyl group and a tricyclodecenyl group; and the like.

The divalent aliphatic hydrocarbon group having 1 to 10 carbon atoms which is represented by R^{2D} may be exemplified by the groups exemplified as the divalent aliphatic hydrocarbon group, which has been exemplified as the aliphatic hydrocarbon group contained in the compound (X1) described above, and the like.

Of these, R^{2B} and R^{2C} each independently represent preferably a hydrogen atom, an alkyl group having 1 to 6 carbon atoms, or —R^{2S}—OH, wherein R^{2D} represents a divalent alkyl group having 1 to 6 carbon atoms.

(X2) Compound

The compound (X2) is a compound having a nitrogen-containing aromatic heterocycle and at least one hydroxy group. The compound (X2) has, for example, at least one divalent aliphatic hydrocarbon group having 1 to 10 carbon atoms bonded to the nitrogen-containing aromatic heterocycle, and at least one hydroxy group bonded to each of the at least one divalent aliphatic hydrocarbon group.

The nitrogen-containing aromatic heterocycle may be exemplified by: an aromatic heterocycle having, as a heteroatom, only a nitrogen atom; an aromatic heterocycle having, as the heteroatom, a nitrogen atom and a heteroatom other than the nitrogen atom; and the like. Examples of the heteroatom other than the nitrogen atom include an oxygen atom, a sulfur atom, and the like. The nitrogen-containing aromatic heterocycle is preferably the aromatic heterocycle having, as the heteroatom, only the nitrogen atom, and examples thereof include: monocyclic nitrogen-containing aromatic heterocycles such as an imidazole ring, a pyridine ring, a pyrazine ring, a pyrazole ring, and a pyridazine ring; polycyclic nitrogen-containing aromatic heterocycles such as a quinazoline ring and a purine ring; and the like. Of these, the nitrogen-containing aromatic heterocycle is preferably the monocyclic nitrogen-containing aromatic heterocycle, and more preferably a pyridine ring.

The compound (X2) has at least one hydroxy group. The hydroxy group preferably bonds to the nitrogen-containing aromatic heterocycle directly or via another group, and more preferably bonds to the nitrogen-containing aromatic heterocycle via the other group. In the case in which the hydroxy group bonds to the nitrogen-containing aromatic heterocycle via the other group, the other group is exemplified by a divalent aliphatic hydrocarbon group having 1 to 10 carbon atoms, and the like. The number of hydroxy group(s) in the compound (X2) is preferably 1 to 5, more preferably 1 to 3, and still more preferably 1 or 2.

The compound (X) is exemplified by compounds represented by formulae (X-1) to (X-10), described later, and the like.

The lower limit of a content of the compound (X) with respect to 1 mol of the compound (M) is preferably 0.3 mol, more preferably 0.5 mol, and still more preferably 1.0 mol. The upper limit of the content with respect to 1 mol of the compound (M) is preferably 10.0 mol, more preferably 5.0 mol, and still more preferably 3.0 mol.

When the content of the compound (X) falls within the above range, the storage stability, the embedding property, the film-thickness-variation-inhibiting property, the etching resistance, and the removability can be further improved.

(C) Compound

The compound (C) is a solvent other than the compound (X). The solvent (C) can be used as a solvent in production of the composition (J), described later.

The solvent (C) is exemplified by an organic solvent. Exemplary organic solvents include an alcohol solvent, a ketone solvent, an ether solvent, an ester solvent, a nitrogen-containing solvent, and the like. The composition (J) may contain one, or two or more types of the solvent (C).

Examples of the alcohol solvent include monohydric alcohol solvents such as methanol, ethanol, and n-propanol; polyhydric alcohol solvents such as ethylene glycol, 1,2-propylene glycol, triethylene glycol, and tripropylene glycol; and the like.

Examples of the ketone solvent include: chain ketone solvents such as methyl ethyl ketone and methyl isobutyl ketone; cyclic ketone solvents such as cyclohexanone; and the like.

Examples of the ether solvent include: polyhydric alcohol ether solvents, e.g., chain ether solvents such as n-butyl ether, and cyclic ether solvents such as tetrahydrofuran and 1,4-dioxane; polyhydric alcohol partial ether solvents such as propylene glycol monoethyl ether, tripropylene glycol monomethyl ether, and tetraethylene glycol monomethyl ether; and the like.

Examples of the ester solvent include: carbonate solvents such as diethyl carbonate; mono ester acetate solvents such as methyl acetate and ethyl acetate; lactone solvents such as γ-butyrolactone; polyhydric alcohol partial ether carboxylate solvents such as diethylene glycol monomethyl ether acetate and propylene glycol monomethyl ether acetate; lactic acid ester solvents such as methyl lactate and ethyl lactate; and the like.

Examples of the nitrogen-containing solvent include: chain nitrogen-containing solvents such as N,N-dimethylacetamide; cyclic nitrogen-containing solvents such as N-methylpyrrolidone; and the like.

The solvent (C) is preferably the ether solvent and/or the ester solvent, more preferably the polyhydric alcohol partial ether solvent and/or the polyhydric alcohol partial ether carboxylate solvent, and still more preferably propylene glycol monoethyl ether and/or propylene glycol monomethyl ether acetate.

The lower limit of a content of the solvent (C) in the composition (J) with respect to 100 parts by mass of the compound (A) is preferably 300 parts by mass, more preferably 500 parts by mass, and still more preferably 700 parts by mass. The upper limit of the content with respect to 100 parts by mass of the compound (A) is preferably 5,000 parts by mass, more preferably 3,000 parts by mass, and still more preferably 2,000 parts by mass.

The lower limit of a content of the solvent (C) in the composition (J) with respect to the composition (J) is preferably 10% by mass, more preferably 15% by mass, and still more preferably 20% by mass. The upper limit of the content with respect to the composition (J) is preferably 99% by mass, and still more preferably 95% by mass.

When the content of the solvent (C) falls within the above ranges, preparation of the composition (J) can be facilitated.

When the composition (J), which can be suitably used as a composition for forming the resist underlayer film, is used as a resist-underlayer-film-forming composition, the resist underlayer film formed from the composition (J) is superior in the film-thickness-variation-inhibiting property, etching resistance, and removability. Furthermore, a superior embedding property when embedding the resist underlayer film in a space in the pattern is attained.

Furthermore, when the composition (J), which can be suitably used as a composition for forming the organic-underlayer-film reverse pattern, is used for forming the organic-underlayer-film reverse pattern, superiority is achieved in the embedding property when forming the organic-underlayer-film reverse pattern from the composition (J). Furthermore, the organic-underlayer-film reverse pattern formed from the composition (J) is superior in the film-thickness-variation-inhibiting property (a property of inhibiting variation of thickness in the pattern), etching resistance, and removability. Thus, when the composition (J) is for use in forming the organic-underlayer-film reverse pattern, a favorable reverse pattern can be formed.

As described above, the composition (J) is superior in coating characteristics; thus, the film formed from the composition (J) inhibits the generation of cracks, even in the case in which the thick film is formed. Therefore, the composition (J) can be suitably used as a composition for forming a thick film. In this case, in manufacturing elements for semiconductors and the like, the composition (J) can be suitably used in, e.g., a process in which a metal-containing film having a high average thickness is required. The composition (J) can be used as a composition for forming a film having an average thickness of no less than 50 nm. The lower limit of the average thickness is preferably 100 nm, more preferably 500 nm, still more preferably 1,000 nm, further preferably 3,000 nm, and especially preferably 4,000 nm.

Other Optional Component(s)

The composition (J) may also contain, for example, an acid generating agent, a high-molecular additive, a surfactant, and/or the like, as other component(s) aside from the compound (A), the compound (X), and the solvent (C).

The acid generating agent is a compound which generates an acid upon exposure to a radioactive ray and/or heating. The composition (J) may contain one, or two or more types of the acid generating agent.

The acid generating agent is exemplified by an onium salt compound, an N-sulfonyloxyimide compound, and the like.

When the composition (J) contains the high-molecular additive, coating characteristics of the composition (J) on the substrate and/or the organic underlayer film can be enhanced. Furthermore, after heating the film formed from the composition (J), inhibiting the generation of cracks in the film is enabled. The composition (J) may contain one, or two or more types of the high-molecular additive.

The high-molecular additive is exemplified by a (poly)oxyalkylene-based high-molecular compound, a fluorine-containing high-molecular compound, a non-fluorine-containing high-molecular compound, and the like.

Examples of the (poly)oxyalkylene-based high-molecular compound include:

polyoxyalkylenes such as (poly)oxyethylene (poly)oxypropylene adducts;

(poly)oxyalkyl ethers such as diethylene glycol heptyl ether, polyoxyethylene oleyl ether, polyoxypropylene butyl ether, polyoxyethylene-polyoxypropylene-2-ethylhexyl ether, and oxyethylene-oxypropylene adducts of higher alcohols having 12 to 14 carbon atoms;

(poly)oxyalkylene (alkyl)aryl ethers such as polyoxypropylene phenyl ether and polyoxyethylene nonylphenyl ether;

acetylene ethers derived from acetylene alcohol by addition polymerization of an alkylene oxide, such as 2,4,7,9-tetramethyl-5-decyne-4,7-diol, 2,5-dimethyl-3-hexyne-2,5-diol, and 3-methyl-1-butyn-3-ol;

(poly)oxyalkylene fatty acid esters such as a diethylene glycol oleic acid ester, a diethylene glycol lauric acid ester, and an ethylene glycol distearic acid ester;

(poly)oxyalkylenesorbitan fatty acid esters such as a polyoxyethylenesorbitan monolauric acid ester and a polyoxyethylenesorbitan trioleic acid ester;

(poly)oxyalkylene alkyl(aryl)ether sulfuric acid ester salts such as sodium polyoxypropylenemethyl ether sulfate and sodium polyoxyethylene dodecylphenol ether sulfate;

(poly)oxyalkylenealkyl phosphoric acid esters such as a (poly)oxyethylenestearyl phosphoric acid ester;

(poly)oxyalkylenealkylamines such as polyoxyethylenelaurylamine; and the like.

The fluorine-containing high-molecular compound may be exemplified by compounds disclosed in Japanese Unexamined Patent Application, Publication No. 2011-89090. Examples of the fluorine-containing high-molecular compound include: a compound including a repeating unit derived from a (meth)acrylate compound having a fluorine atom, and a repeating unit derived from a (meth)acrylate compound having at least two (preferably at least five) alkyleneoxy groups (preferably ethyleneoxy groups or propyleneoxy groups); and the like.

Examples of the non-fluorine-containing high-molecular compound include compounds having one, or two or more types of repeating unit(s) derived from (meth)acrylate monomer(s), for example:

chain or branched alkyl (meth)acrylates such as lauryl (meth)acrylate, 2-ethylhexyl (meth)acrylate, n-butyl (meth)acrylate, t-butyl (meth)acrylate, isooctyl (meth)acrylate, isostearyl (meth)acrylate, and isononyl (meth)acrylate;

alkoxyethyl (meth)acrylates such as methoxyethyl (meth)acrylate;

alkylene glycol di(meth)acrylates such as ethylene glycol di(meth)acrylate and 1,3-butylene glycol di(meth)acrylate;

hydroxyalkyl (meth)acrylates such as 2-hydroxyethyl (meth)acrylate, 2-hydroxypropyl (meth)acrylate, 2-hydroxybutyl (meth)acrylate, and 4-hydroxybutyl (meth) acrylate;

dicyclopentenyloxyethyl (meth)acrylate;

nonylphenoxypolyethylene glycol (meth)acrylate (having a —(CH₂CH₂O)ₙ— structure wherein n is 1 to 17); and/or the like.

When the composition (J) contains the surfactant, coating characteristics of the composition (J) on the substrate and/or the organic underlayer film can be enhanced. Furthermore, after heating the film formed from the composition (J), inhibiting the generation of cracks in the film is enabled. The composition (J) may contain one, or two or more types of the surfactant.

Examples of a commercially available product of the surfactant include: “Newcol 2320,” “Newcol 714-F,” “Newcol 723,” “Newcol 2307” and “Newcol 2303” (all available from Nippon Nyukazai Co., Ltd.); “Pionin D-1107-S,” “Pionin D-1007,” “Pionin D-1106-DIR,” “Newkalgen TG310,” “Pionin D-6105-W,” “Pionin D-6112,” and “Pionin D-6512,” (all available from TAKEMOTO OIL & FAT Co., Ltd); “Surfynol 420,” “Surfynol 440,” “Surfynol 465,” and “Surfynol 2502” (all available from Air Products Japan K.K.); “Megaface F171,” “Megaface F172,” “Megaface F173,” “Megaface F176,” “Megaface F177,” “Megaface F141,” “Megaface F142,” “Megaface F143,” “Megaface F144,” “Megaface R30,” “Megaface F437,” “Megaface F475,” “Megaface F479,” “Megaface F482,” “Megaface F562,” “Megaface F563,” “Megaface F780,” “Megaface R-40,” “Megaface DS-21,” “Megaface RS-56,” “Megaface RS-90,” and “Megaface RS-72-K” (all available from DIC Corporation), “Fluorad FC430” and “Fluorad FC431,” (both available from Sumitomo 3M Limited); “ASAHI GUARD AG710,” “Surflon S-382,” “Surflon SC-101,” “Surflon SC-102,” “Surflon SC-103,” “Surflon SC-104,” “Surflon SC-105,” and “Surflon SC-106” (all available from Asahi Glass Co., Ltd.); “FTX-218” and “NBX-15” (both available from NEOS COMPANY LIMITED); and the like.

In the case in which the composition (J) contains the other optional component(s), a content of the other optional component(s) in the composition (J) may be appropriately determined in accordance with type(s), etc. of the other optional component(s). The upper limit of the content of the other optional component(s) with respect to 100 parts by mass in total of the compound (A) and the compound (X) is preferably 30 parts by mass, and more preferably 20 parts by mass.

### Method of Producing Film-Forming-Composition

A method of producing a film-forming composition (the composition (J)) of a yet further embodiment of the present invention includes: a step (hereinafter, may be also referred to as “mixing step”) of mixing the compound (M) and the compound (X); and a step (hereinafter, may be also referred to as “water-adding step”) of adding water to a mixture obtained by the mixing step.

The method of producing a film-forming composition may further include, after the mixing step and before the water-adding step, a step (hereinafter, may be also referred to as “diluting step”) of diluting with a solvent (B), the mixture obtained by the mixing step. Furthermore, the method of producing a film-forming composition may further include, after the water-adding step: a step (hereinafter, may be also referred to as “solvent-adding step”) of adding the solvent (C) to the mixture obtained by the water-adding step; and a step (hereinafter, may be also referred to as “solvent-eliminating step”) of eliminating excess water and the excess solvent (B) from the mixture obtained by the solvent-adding step. Moreover, the method of producing a film-forming composition may further include, after the solvent-eliminating step, a step (hereinafter, may be also referred to as “solvent-re-adding step”) of further adding the solvent (C).

Mixing Step

In this step, the compound (M) and the compound (X) are mixed. Specifically, for example, the compound (M) and the compound (X) are added dropwise over a predetermined time period and then heated at a predetermined temperature, followed by cooling to no greater than 30° C. The predetermined time period may be appropriately set. For example, the lower limit of the predetermined time period for the dropwise addition is preferably 10 min, and more preferably 20 min. On the other hand, the upper limit of the predetermined time period for the dropwise addition is preferably 60 min, and more preferably 40 min. The predetermined temperature may be appropriately set. For example, the lower limit of the predetermined heating temperature is preferably 45° C., and more preferably 50° C. On the other hand, the upper limit of the predetermined heating temperature is preferably 75° C., and more preferably 70° C.

It is to be noted that in the method of producing a film-forming composition, due to mixing the compound (M) and the compound (X) in the mixing step and then adding water in the water-adding step, to be described later, a hydrolytic condensation reaction of the compound (M) is allowed to proceed. More specifically, mixing the compound (M) with the compound (X) beforehand, and then allowing the hydrolytic condensation reaction of the compound (M) to proceed in the presence of the compound (X) enables preparing the composition (J) being superior in the embedding property and storage stability.

Diluting Step

In this step, after the mixing step, the mixture obtained by the mixing step is diluted with the solvent (B). Specifically, the mixture obtained by the mixing step is diluted with the solvent (B) such that the compound (M) reaches a predetermined concentration. When the method of producing a film-forming composition includes the diluting step, the concentration of the compound (M) can be adjusted, and as a result, the film thickness of the metal-containing film can be adjusted.

The solvent (B) is not particularly limited as long as it is capable of dissolving or dispersing the compound (M) and compound (X), as well as the other component(s), which is/are contained as needed. The solvent (B) is exemplified by an alcohol solvent, a ketone solvent, an ether solvent, an ester solvent, a nitrogen-containing solvent, and the like. These solvents are exemplified by solvents similar to those exemplified as the solvent (C) contained in the composition (J) described above. In this step, one, or two or more types of the solvent (B) may be used.

The solvent (B) is preferably the alcohol solvent. Examples of the alcohol solvent include methanol, ethanol, isopropyl alcohol, 1-propanol, 1-butanol, and the like.

Water-Adding Step

In this step, water is added to the mixture. In the case in which the method of producing a film-forming composition includes the diluting step, in this water-adding step, water is added to the mixture after the diluting. Specifically, for example, water is added dropwise at room temperature (25° C. to 30° C.) over a predetermined time period while stirring the mixture after the diluting. The predetermined time period for the dropwise addition may be appropriately set. For example, the lower limit of the predetermined time period for dropwise addition is preferably 5 min, and more preferably 10 min. On the other hand, the upper limit of the predetermined time period for dropwise addition is preferably 40 min, and more preferably 30 min.

When water is added to the compound, a hydrolytic condensation reaction of the compound (M) is caused. In accordance with an advancement situation of the hydrolytic condensation reaction of the compound (M), heating may be conducted after adding water to the mixture. By the heating, the hydrolytic condensation reaction of the compound (M) can be promoted. In the case of conducting the heating, a heating temperature may be appropriately set. The lower limit of the heating temperature is preferably 45° C., and more preferably 50° C. The upper limit of the heating temperature is preferably 75° C., and more preferably 70° C. In the case of conducting the heating, a heating time period may be appropriately set. The lower limit of the heating time period is preferably 60 min, and more preferably 90 min. The upper limit of the time period is preferably 180 min, and more preferably 150 min.

Solvent-Adding Step

In this step, the solvent (C) is added to the mixture obtained by the water-adding step. The solvent (C) used in this step is described as the solvent (C) in the “Composition (J)” above. The solvent (C) is preferably the ether solvent and/or the ester solvent, more preferably the polyhydric alcohol partial ether solvent and/or the polyhydric alcohol partial ether carboxylate solvent, and still more preferably propylene glycol monoethyl ether and/or propylene glycol monomethyl ether acetate.

Solvent-Eliminating Step

In this step, the excess water and the excess solvent (B) are eliminated from the mixture obtained by the water-adding step. In order to eliminate the excess water and the excess solvent (B), for example, a rotary evaporator can be used. Furthermore, a solution obtained by the solvent-eliminating step may be filtered through, for example, a filter having a pore size of no greater than 0.2 sm. The mixture obtained by this step (hereinafter, may be also referred to as (“(Z) mixture” or “mixture (Z)”) may be used directly as the composition (J), or a mixture obtained by subjecting this mixture to the solvent-re-adding step, described later, may be used as the composition (J).

Solvent Re-Adding Step

In this step, after, the solvent-eliminating step, the solvent (C) is further added. Specifically, the solvent (C) is added to the mixture (Z) obtained by the solvent-eliminating step. When the method of producing a film-forming composition includes this step, a concentration of the components other than the solvent which are contained in the mixture (Z) can be adjusted.

### Resist Underlayer Film

The resist underlayer film of another embodiment of the present invention is formed by using the composition (J) as the resist-underlayer-film-forming composition. The resist underlayer film is the metal-containing film. Since the resist underlayer film is formed by using the composition (J), superiority is achieved in the film-thickness-variation-inhibiting property, etching resistance, and removability.

An average thickness of the resist underlayer film is not particularly limited, and can be appropriately determined. The lower limit of the average thickness of the resist underlayer film is preferably 1 nm, more preferably 5 nm, and still more preferably 10 nm. The upper limit of the average thickness is preferably 10,000 nm, more preferably 7,000 nm, and still more preferably 6,000 nm.

As described above, with regard to the resist underlayer film formed from the composition (J), the occurrence of cracks is inhibited, even in the case of the thick film being formed. Thus, the resist underlayer film can be suitably used in, e.g., the process in which the resist underlayer film having the high average thickness is required, in manufacturing elements for semiconductors and the like. The lower limit of the average thickness in the case of using the resist underlayer film for such an intended usage is preferably 100 nm, more preferably 500 nm, still more preferably 1,000 nm, further preferably 3,000 nm, and particularly preferably 4,000 nm.

### Method of Forming Film

The method of forming a film of a still another embodiment of the present invention includes a step (hereinafter, may be also referred to as “film-forming-composition-applying step”) of applying a film-forming composition directly or indirectly on a substrate. In the film-forming-composition-applying step, the composition (J) described above is used as the film-forming composition. The method of forming a film enables forming a film being superior in each of the film-thickness-variation-inhibiting property, etching resistance, and removability.

The film-forming-composition-applying step included in the method of forming a film will be described below.

Film-Forming-Composition-Applying Step

In this step, the film-forming composition is applied directly or indirectly on the substrate. In this step, the composition (J) described above is used as the film-forming composition. By this step, a coating film is formed directly or indirectly on the substrate. A film is formed from the coating film by evaporation or the like of the solvent (C). The film formed by this step is the metal-containing film.

The substrate is exemplified by a metal substrate, a silicon wafer, and the like. The “metal substrate” refers to a substrate containing a metal atom in at least a part of a surface layer thereof. The metal atom contained in the metal substrate is not particularly limited as long as it is an atom of a metal element. Silicon and boron do not fall under the category of the metal atom. Examples of the metal atom include copper, iron, zinc, cobalt, aluminum, tin, tungsten, zirconium, titanium, tantalum, germanium, molybdenum, ruthenium, gold, silver, platinum, palladium, nickel, and the like. Examples of the metal substrate include a substrate made of metal, a silicon water coated with metal, and the like. A silicon nitride film, an alumina film, a silicon dioxide film, a tantalum nitride film, a titanium nitride film, or the like may be formed on a part of the metal substrate.

The substrate may be a pattern-unformed substrate, or may be a pattern-formed substrate.

The pattern on the pattern-formed substrate is exemplified by a line-and-space pattern or a trench pattern, with line widths of space portions being no greater than 2,000 nm, no greater than 1,000 nm, no greater than 500 nm, or no greater than 50 nm; a hole pattern, with diameters of holes being no greater than 300 nm, no greater than 150 nm, no greater than 100 nm, or no greater than 50 nm; and the like.

Furthermore, with respect to dimensions of the pattern formed on the substrate, an exemplary fine pattern may have: a height of no less than 100 nm, no less than 200 nm, or no less than 300 nm; a width of no greater than 50 nm, no greater than 40 nm, or no greater than 30 nm; and an aspect ratio (pattern height/pattern width) of no less than 3, no less than 5, or no less than 10.

It is to be noted that in the case in which the pattern-formed substrate is used as the substrate, a coating film formed by applying the film-forming composition of the one embodiment of the present invention on the substrate preferably enables recessed portions of the pattern to be filled therewith.

In this step, in order to promote the formation of the film, the coating film may be heated. An atmosphere for heating the coating film is exemplified by ambient air, a nitrogen atmosphere, and the like. The lower limit of a temperature in the heating is preferably 60° C. The upper limit of the temperature is preferably 150° C. The lower limit of a time period of the heating is preferably 10 sec, and more preferably 30 sec. The upper limit of the time period is preferably 300 sec, and more preferably 180 sec.

The heating of the coating film may be conducted as a preheating, with the coating film being further heated after the preheating. This heating is typically carried out in an ambient air, but may be carried out in a nitrogen atmosphere. The lower limit of a temperature in the heating is preferably 200° C., more preferably 250° C., and still more preferably 300° C. The upper limit of the temperature is preferably 600° C., more preferably 500° C., and still more preferably 400° C. The lower limit of a time period of the heating is preferably 15 sec, and more preferably 30 sec. The upper limit of the time period is preferably 1,200 sec, and more preferably 600 sec.

In the method of forming a film, exposing may be combined with the heating. A radioactive ray to be used in the exposing may be appropriately selected in accordance with a type of the acid generating agent, and examples of the radioactive ray include: electromagnetic waves such as a visible light ray, an ultraviolet ray, a far ultraviolet ray, an X-ray, and a γ-ray; and particle rays such as an electron beam, a molecular beam, and an ion beam.

An average thickness of the film to be formed is not particularly limited, and may be appropriately determined. The lower limit of the average thickness is preferably 1 nm, more preferably 5 nm, and still more preferably 10 nm. The upper limit of the average thickness is preferably 10,000 nm, more preferably 7,000 nm, and still more preferably 6,000 nm.

As described above, the film formed from the composition (J) inhibits the occurrence of cracks even in the case of the thick film being formed. Thus, the method of forming a film can be suitably employed in, e.g., the process in which the metal-containing film having the high average thickness is required, in manufacturing elements for semiconductors and the like. In the case of using the method of forming a film in such a process, the lower limit of the average thickness of the film to be formed is preferably 50 nm, more preferably 100 nm, still more preferably 200 nm, further preferably 500 nm, and especially preferably 1,000 nm.

### Method of Forming Resist Pattern

The method of forming a resist pattern of yet another embodiment of the present invention includes: a step (hereinafter, may be also referred to as “film-forming-composition-applying step”) of applying a film-forming composition directly or indirectly on a substrate; a step (hereinafter, may be also referred to as “organic-resist-film-forming-composition-applying step”) of applying an organic-resist-film-forming composition directly or indirectly on a resist underlayer film formed by the film-forming-composition-applying step; a step (hereinafter, may be also referred to as “exposing step”) of exposing to a radioactive ray, an organic resist film formed by the organic-resist-film-forming composition-applying-step; and a step (hereinafter, may be also referred to as “developing step”) of developing the organic resist film exposed.

The method of forming a resist pattern may include, before the film-forming-composition-applying step, a step (hereinafter, may be also referred to as “organic-underlayer-film-forming step”) of forming an organic underlayer film directly or indirectly on the substrate. Furthermore, the method of forming a resist pattern may further include, after the developing step, a step (hereinafter, may be also referred to as “etching step”) of carrying out etching using a resist pattern formed by the developing step as a mask. As needed, the method of forming a resist pattern may include, before the organic-resist-film-forming-composition-applying step, a step (hereinafter, may be also referred to as “silicon-containing-film-forming step”) of forming a silicon-containing film on the resist underlayer film formed by the film-forming-composition-applying step.

Since the method of forming a resist pattern uses the composition (J), a favorable resist pattern can be formed.

Each step included in the method of forming a resist pattern will be described below.

Organic-Underlayer-Film-Forming Step

In this step, the organic underlayer film is formed on the substrate. The substrate may be exemplified by substrates similar to those used in the film-forming step in the method of forming a film of the still another embodiment of the present invention, described above. The organic underlayer film may be exemplified by organic underlayer films similar to those formed by the method of forming an organic-underlayer-film reverse pattern, described later.

Film-Forming-Composition-Applying Step

In this step, the film-forming composition is applied directly or indirectly on the substrate. The case in which the film-forming composition is applied indirectly on the substrate may be exemplified by a case in which the film-forming composition is applied on the organic underlayer film formed on the substrate by the organic-underlayer-film-forming step, and the like. In this step, the composition (J) described above is used as the film-forming composition. By this step, the resist underlayer film is formed directly or indirectly on the substrate. This step is similar to the film-forming-composition-applying step in the method of forming a film of the still another embodiment of the present invention, described above.

Silicon-Containing-Film-Forming Step

In this step, a silicon-containing film is formed on the resist underlayer film formed by the film-forming-composition-applying step.

The silicon-containing film is formed by, for example, subjecting a coating film formed by applying a silicon-containing-film-forming composition on the resist underlayer film to, typically, exposure and/or heating, thereby allowing for hardening. As a commercially available product of the silicon-containing-film-forming composition, for example, “NFC SOG01,” “NFC SOG04,” or “NFC SOG080” (all available from JSR Corporation), or the like may be used.

Examples of the radioactive ray which may be used for the exposure include: electromagnetic waves such as a visible light ray, an ultraviolet ray, a far ultraviolet ray, an X-ray, and a γ-ray; particle rays such as an electron beam, a molecular beam, and an ion beam; and the like.

The lower limit of a temperature when heating the coating film is preferably 90° C., more preferably 150° C., and still more preferably 180° C. The upper limit of the temperature is preferably 550° C., more preferably 450° C., and still more preferably 300° C.

Organic-Resist-Film-Forming-Composition-Applying Step

In this step, the organic-resist-film-forming composition is applied on the resist underlayer film formed by the film-forming-composition-applying step. In the case in which the silicon-containing-film-forming step was carried out, the organic-resist-film-forming composition is applied on the silicon-containing film.

In this step, specifically, the organic resist film is formed by: applying the organic-resist-film-forming composition such that a resultant organic resist film has a predetermined thickness, followed by subjecting the organic resist film to heating to evaporate away the solvent contained in the coating film.

Examples of the organic-resist-film-forming composition include: a chemically amplified positive or negative resist composition that contains a radiation-sensitive acid generating agent; a positive resist composition containing an alkali-soluble resin and a quinone diazide-based photosensitizing agent; a negative resist composition containing an alkali-soluble resin and a crosslinking agent; and the like.

The organic-resist-film-forming composition is used for forming the organic resist film, typically, after filtering through a filter having a pore size of no greater than 0.2 μm, for example. It is to be noted that in this step, a commercially available organic resist composition may be used directly.

A procedure for applying the organic-resist-film-forming composition is not particularly limited, and is exemplified by a spin coating procedure and the like. Furthermore, a heating temperature may be appropriately adjusted in accordance with the type of the organic-resist-film-forming composition used. The lower limit of the temperature of the heating is preferably 30° C., and more preferably 50° C. The upper limit of the temperature is preferably 200° C., and more preferably 150° C. The lower limit of a time period of the heating is preferably 10 sec, and more preferably 30 sec. The upper limit of the time period is preferably 600 sec, and more preferably 300 sec.

Exposing Step

In this step, the organic resist film formed by the organic-resist-film-forming composition-applying step is exposed to a radioactive ray.

The radioactive ray for use in the exposure may be appropriately selected from: electromagnetic waves such as a visible light ray, an ultraviolet ray, a far ultraviolet ray, an X-ray, and a γ-ray; and particle rays such as an electron beam, a molecular beam, and an ion beam, depending on the type of the radiation-sensitive acid generating agent, quinone diazide-based photosensitizing agent, and crosslinking agent to be used in the organic-resist-film-forming composition. Among these, far ultraviolet rays are preferred; and a KrF excimer laser beam (wavelength: 248 nm), an ArF excimer laser beam (wavelength: 193 nm), an F₂ excimer laser beam (wavelength: 157 nm), a Kr₂ excimer laser beam (wavelength: 147 nm), an ArKr excimer laser beam (wavelength: 134 nm), or an extreme ultraviolet ray (EUV; wavelength: 13.5 nm, etc.) is more preferred; and a KrF excimer laser beam, an ArF excimer laser beam, or an EUV is still more preferred.

After the exposing, heating may be conducted to improve the resolution, pattern profile, developability, and the like. A temperature of the heating may be appropriately adjusted in accordance with the type of the organic-resist-film-forming composition used. The lower limit of the temperature of the heating is preferably 50° C., and more preferably 70° C. The upper limit of the temperature is preferably 200° C., and more preferably 150° C. The lower limit of a time period of the heating is preferably 10 sec, and more preferably 30 sec. The upper limit of the time period is preferably 600 sec, and more preferably 300 sec.

Developing Step

In this step, the organic resist film exposed is developed. The development may be either a development with an alkali or a development with an organic solvent. In the case of the development with an alkali, examples of the developer solution include basic aqueous solutions of sodium hydroxide, potassium hydroxide, sodium carbonate, sodium silicate, sodium metasilicate, ammonia, ethylamine, n-propylamine, diethylamine, di-n-propylamine, triethylamine, methyldiethylamine, dimethylethanolamine, triethanolamine, tetramethylammonium hydroxide (TMAH), tetraethyl ammonium hydroxide, pyrrole, piperidine, choline, 1,8-diazabicyclo[5.4.0]-7-undecene, 1,5-diazabicyclo[4.3.0]-5-nonene, or the like. To the basic aqueous solution, a water-soluble organic solvent, e.g., alcohols such as methanol and ethanol, a surfactant, etc., may be added, each in an appropriate amount. Alternatively, in the case of the development with an organic solvent, examples of the developer solution include various organic solvents exemplified as the solvent (C) of the composition (J) described above, and the like.

A predetermined resist pattern is formed by the development with the developer solution, followed by washing and drying.

Etching Step

In this step, etching is carried out using the resist pattern, which was formed by the developing step, as a mask to form a pattern on the substrate. The etching may be conducted once or multiple times. In other words, the etching may be conducted sequentially using patterns obtained by the etching as masks, and in light of obtaining a pattern having a more favorable shape, the etching is preferably conducted multiple times. In the case in which the etching is conducted multiple times, the silicon-containing film, the resist underlayer film, and the substrate are subjected to the etching sequentially in this order. An etching procedure may be exemplified by dry etching, wet etching, and the like. Of these, in light of making the shape of the substrate pattern more favorable, the dry etching is preferred. In the dry etching, for example, gas plasma such as oxygen plasma, or the like may be used. After the etching, the patterned substrate having a predetermined pattern is obtained.

### Method of Forming Organic-Underlayer-Film Reverse Pattern

The method of forming an organic-underlayer-film reverse pattern of a further embodiment of the present invention includes: a step (hereinafter, may be also referred to as “organic-underlayer-film-forming step”) of forming an organic underlayer film directly or indirectly on a substrate; a step (hereinafter, may be also referred to as “resist pattern-forming step”) of forming a resist pattern directly or indirectly on the organic underlayer film; a step (hereinafter, may be also referred to as “organic-underlayer-film-pattern-forming step”) of forming an organic-underlayer-film pattern on the organic underlayer film by carrying out etching using the resist pattern as a mask; a step (hereinafter, may be also referred to as “organic-underlayer-film-reverse-pattern-forming-film-forming step”) of using a composition (J1) to form an organic-underlayer-film-reverse-pattern-forming film directly or indirectly on the organic-underlayer-film pattern; and a step (hereinafter, may be also referred to as “organic-underlayer-film-reverse-pattern-forming step”) of forming an organic-underlayer-film reverse pattern by removing the organic-underlayer-film pattern. In the method of forming an organic-underlayer-film reverse pattern, before the resist pattern-forming step, a step (hereinafter, may be also referred to as “resist-intermediate-film-forming step”) of forming a resist intermediate film on the organic underlayer film formed by the organic-underlayer-film-forming step may be included as needed. In the organic-underlayer-film-reverse-pattern-forming-film-forming step, the organic-underlayer-film-reverse-pattern-forming film is formed by using the composition (J) described above.

Since the method of forming an organic-underlayer-film reverse pattern uses the composition (J), a favorable reverse pattern can be formed.

Each step included in the method of forming an organic-underlayer-film reverse pattern will be described below.

Organic-Underlayer-Film-Forming Step

In this step, the organic underlayer film is formed on the substrate. The substrate may be exemplified by substrates similar to those used in the film-forming step, described above.

The organic underlayer film may be formed from an organic compound. Examples of the organic compound include commercial available products such as “NFC HM8006,” available from JSR Corporation, and the like. The organic underlayer film may be formed by applying an organic-underlayer-film-forming composition by a spin coating procedure or the like to form a coating film, and then heating.

The lower limit of an average thickness of the organic underlayer film to be formed is preferably 10 nm, more preferably 50 nm, and still more preferably 100 nm. The upper limit of the average thickness is preferably 1,000 nm, and more preferably 500 nm.

Resist-Intermediate-Film-Forming Step

In this step, the resist intermediate film is formed on the organic underlayer film formed by the organic-underlayer-film-forming step. Examples of the resist intermediate film include commercially available products such as: “NFC SOG01,” “NFC SOG4,” and “NFC SOG080,” each available from JSR Corporation, and the like. Alternatively, a polysiloxane, titanium oxide, aluminum oxide, tungsten oxide, or the like that is formed by a CVD process may be used. A procedure of forming the resist intermediate film is not particularly limited, and for example, a coating procedure, a CVD process, or the like may be employed. Of these, the coating procedure is preferred. When the coating procedure is employed, the resist intermediate film may be consecutively formed after forming the organic underlayer film.

Resist Pattern-Forming Step

In this step, the resist pattern is formed on the organic underlayer film and the resist intermediate film. In this step, a procedure of forming the resist pattern may be exemplified by a well-known procedure such as a procedure of using a resist composition, a procedure in which a nanoimprint lithography technique is employed, and the like.

Organic-Underlayer-Film-Pattern-Forming Step

In this step, the organic underlayer film is etched using as a mask, the resist pattern. The etching procedure may be exemplified by dry etching, wet etching, and the like. The dry etching may be carried out using a well-known dry etching apparatus. Furthermore, as a source gas used at the time of the dry etching: a fluorine-based gas such as CHF₃, CF₄, C₂F₆, C₃F₈, or SF₆; a chlorine-based gas such as Cl₂ or BCl₃; an oxygen-based gas such as O₂ or O₃; a reducing gas such as H₂, NH₃, CO, CO₂, CH₄, C₂H₂, C₂H₄, C₂H₆, C₃H₄, C₃H₆, C₃H₈, HF, HI, HBr, HCl, NO, NH₃, or BCl₃; an inert gas such as He, N₂, or Ar; or the like may be used, although the selection may depend on the elemental composition of the film to be etched, or a mixture of these gases may also be used. For the dry etching of the resist intermediate film in the case of forming the resist intermediate film, typically, a fluorine-based gas is used, and for the dry etching of the organic underlayer film, an oxygen-based gas may be suitably used.

The organic-underlayer-film pattern thus formed is exemplified by a line-and-space pattern or a trench pattern, with line widths of space portions being no greater than 2,000 nm, no greater than 1,000 nm, no greater than 500 nm, or no greater than 50 nm; a hole pattern, with diameters of holes being no greater than 300 nm, no greater than 150 nm, no greater than 100 nm, or no greater than 50 nm; and the like.

Furthermore, with respect to dimensions of the organic-underlayer-film pattern, an exemplary fine pattern may have: a height of no less than 100 nm, no less than 200 nm, or no less than 300 nm; a width of no greater than 50 nm, no greater than 40 nm, or no greater than 30 nm; and an aspect ratio (pattern height/pattern width) of no less than 3, no less than 5, or no less than 10.

Organic-Underlayer-Film-Reverse-Pattern-Forming-Film-Forming Step

In this step, the composition (J) is embedded in spaces of the organic-underlayer-film pattern. Specifically, the composition (J) is applied, on the substrate having the organic-underlayer-film pattern formed thereon, by an appropriate coating procedure such as spin coating, cast coating, roll coating, or the like, whereby the composition (J) is embedded in the spaces of the organic-underlayer-film pattern. Furthermore, in this step, after the composition (J) is embedded into the spaces of the organic-underlayer-film pattern, a drying step is preferably provided. A drying procedure is not particularly limited, and the organic solvent in the composition (J) can be evaporated away by baking, for example. Conditions of the baking may be appropriately adjusted depending on the blend composition of the composition (J), and a temperature of the baking is typically 80 to 250° C., and preferably 80 to 200° C. In a case in which the temperature of the baking is 80 to 180° C., a flattening step described later, especially a flattening processing by a wet etching back procedure, can be smoothly carried out. It is to be noted that a time period of the heating is typically 10 to 300 sec, and preferably 30 to 180 sec. Furthermore, a thickness of the organic-underlayer-film-reverse-pattern-forming film to be obtained after the drying is not particularly limited, and is typically 10 to 1,000 nm, and preferably 20 to 500 nm.

Organic-Underlayer-Film-Reverse-Pattern-Forming Step

In this step, the organic-underlayer-film pattern is removed to form the organic-underlayer-film reverse pattern.

Specifically, first, the flattening processing is preferably carried out in order to expose an upper surface of the organic-underlayer-film pattern. Next, the organic-underlayer-film pattern is removed by dry etching or dissolving and removing, whereby a predetermined organic-underlayer-film reverse pattern is obtained.

This organic-underlayer-film-reverse-pattern-forming step enables forming on the substrate, a fine pattern having a high aspect ratio, which is difficult to achieve by a conventional lithography process. Accordingly, the fine pattern can be transferred to the substrate.

As a flattening procedure to be employed in the flattening processing, an etching procedure such as dry etching back or wet etching back, a CMP procedure, or the like may be employed. Of these, in light of low cost, the dry etching back in which a fluorine-based gas or the like is used, or the wet etching back is preferred. It is to be noted that processing conditions in the flattening processing are not particularly limited, and may be appropriately adjusted.

In addition, for removal of the organic-underlayer-film pattern, dry etching is preferred, and specifically, oxygen-based gas etching, ozone etching, or the like is preferably employed. For the dry etching, a well-known apparatus such as an oxygen plasma ashing apparatus or an ozone ashing apparatus may be used. It is to be noted that the etching processing conditions are not particularly limited, and may be appropriately adjusted.

Metal-Containing-Film-Removing Step

In this step, the organic-underlayer-film reverse pattern is removed with a removing liquid (I) containing an acid or a base.

The removing liquid (I) containing the acid is exemplified by: a liquid containing an acid and water; a liquid obtained by mixing an acid, hydrogen peroxide and water; and the like. Examples of the acid include sulfuric acid, hydrofluoric acid, hydrochloric acid, phosphoric acid, and the like. More specific examples of the removing liquid (I) containing the acid include: a liquid obtained by mixing hydrofluoric acid and water; a liquid obtained by mixing sulfuric acid, hydrogen peroxide, and water; a liquid obtained by mixing hydrochloric acid, hydrogen peroxide, and water; and the like.

The removing liquid (I) containing the base is exemplified by: a liquid containing a base and water; a liquid obtained by mixing a base, hydrogen peroxide, and water; and the like, and the liquid obtained by mixing a base, hydrogen peroxide, and water is preferred.

Examples of the base include sodium hydroxide, potassium hydroxide, sodium carbonate, sodium silicate, sodium metasilicate, ammonia, ethylamine, n-propylamine, diethylamine, di-n-propylamine, triethylamine, methyldiethylamine, dimethylethanolamine, triethanolamine, tetramethylammonium hydroxide (TMAH), tetraethylammonium hydroxide, pyrrole, piperidine, choline, 1,8-diazabicyclo[5.4.0]-7-undecene, and 1,5-diazabicyclo[4.3.0]-5-nonene, and the like. Of these, ammonia is preferred.

The lower limit of a temperature in the removing step is preferably 20° C., more preferably 40° C., and still more preferably 50° C. The upper limit of the temperature is preferably 300° C., and more preferably 100° C.

The lower limit of a time period of the removing step is preferably 5 sec, and more preferably 30 sec. The upper limit of the time period is preferably 10 min, and more preferably 180 sec.

### Method of Forming Metal-Containing Film Pattern

The method of forming a metal-containing film pattern of the still further embodiment of the present invention includes: a step (hereinafter, may be also referred to as “metal-containing-film-forming-composition-applying step”) of applying a metal-containing-film-forming composition directly or indirectly on a substrate; a step (hereinafter, may be also referred to as “organic-underlayer-film-forming step”) of forming an organic underlayer film directly or indirectly on a metal-containing film formed by the metal-containing-film-forming-composition-applying step; a step (hereinafter, may be also referred to as “resist pattern-forming step”) of forming a resist pattern directly or indirectly on the organic underlayer film; and a step (hereinafter, may be also referred to as “etching step”) of forming a pattern on the metal-containing film by carrying out etching using the resist pattern as a mask. In the metal-containing-film-forming-composition-applying step, the composition (J) described above is used as the metal-containing-film-forming composition. As needed, the method of forming a metal-containing film pattern may include, before the resist pattern-forming step, a step (hereinafter, may be also referred to as “silicon-containing-film-forming step”) of forming a silicon-containing film on the organic underlayer film.

The method of forming a metal-containing film pattern enables forming a favorable metal-containing film pattern.

Each step included in the method of forming a metal-containing film pattern will be described below.

Metal-Containing-Film-Forming-Composition-Applying Step

In this step, the metal-containing-film-forming-composition is applied directly or indirectly on the substrate. In this step, the composition (J) described above is used as the metal-containing-film-forming composition. By this step, a coating film is formed directly or indirectly on the substrate. The metal-containing film is formed by evaporation or the like of the solvent (C) from the coating film.

The substrate is exemplified by substrates similar to those exemplified as the substrate used in the film-forming step in the method of forming a film of the still another embodiment of the present invention. Furthermore, this step may be carried out by an operation similar to that of the film-forming step in the method of forming a film, described above.

An average thickness of the metal-containing film formed by this step is not particularly limited, and may be appropriately determined. The lower limit of the average thickness of the metal-containing film is preferably 1 nm, more preferably 5 nm, and still more preferably 10 nm. The upper limit of the average thickness is preferably 10,000 nm, more preferably 7,000 nm, and still more preferably 6,000 nm.

As described above, the film formed from the composition (J) inhibits the occurrence of cracks, even in the case of the thick film being formed. Thus, the metal-containing film formed by this step may be the thick film. The lower limit of the average thickness of the metal-containing film in this case is preferably 100 nm, more preferably 500 nm, still more preferably 1,000 nm, further preferably 3,000 nm, and particularly preferably 4,000 nm. In the case of the metal-containing film being the thick film, a height of the metal-containing film pattern formed by the method of forming a metal-containing film pattern becomes greater. Thus, for example, in the case of carrying out etching using the metal-containing-film pattern as the mask, a film and/or the substrate situated below the metal-containing film pattern may be more deeply etched.

Organic-Underlayer-Film-Forming Step

In this step, the organic underlayer film is formed directly or indirectly on the metal-containing film formed by the metal-containing-film-forming-composition-applying step. By this step, the organic underlayer film is formed directly or indirectly on the metal-containing film. This step is similar to the organic-underlayer-film-forming step in the method of forming an organic-underlayer-film reverse pattern of the further embodiment of the present invention, described above.

Silicon-Containing-Film-Forming Step

In this step, the silicon-containing film is formed on the organic underlayer film. This step is similar to the silicon-containing-film-forming step in the method of forming a resist pattern of the yet another embodiment of the present invention, described above.

Resist Pattern-Forming Step

In this step, the resist pattern is formed directly or indirectly on the organic underlayer film. By this step, the resist pattern is formed directly or indirectly on the organic underlayer film. This step is similar to the resist pattern-forming step in the method of forming an organic-underlayer-film reverse pattern of the further embodiment of the present invention, described above.

Etching Step

In this step, the pattern is formed on the metal-containing film by carrying out etching using the resist pattern as the mask. By this step, the metal-containing film pattern is formed. This step is similar to the etching step in the method of forming a resist pattern of the yet another embodiment of the present invention, described above. It is to be noted that in forming the pattern on the metal-containing film by etching, the organic underlayer film formed directly or indirectly on the metal-containing film is also etched.

### EXAMPLES

Hereinafter, Examples are described. It is to be noted that the following Examples merely illustrate typical Examples of the embodiments of the present invention, and the Examples should not be construed to narrow the scope of the present invention.

In the present Examples, a concentration of components other than the solvent in a mixture (Z), a weight average molecular weight (Mw) of a hydrolytic condensation product in the mixture (Z), and an average thickness of a film were measured by the following methods.

Concentration of Components Other than Solvent in Mixture (Z)

The concentration (% by mass) was determined by: baking 0.5 g of the mixture (Z) at 250° C. for 30 min; measuring a mass of a residue thus obtained; and dividing the mass of the residue by the mass of the mixture (Z).

Weight Average Molecular Weight (Mw) of Hydrolytic Condensation Product of Mixture (Z)

Measurements were carried out by gel permeation chromatography (detector: differential refractometer) by using GPC columns (“AWA-H”×2, “AW-H”×1, and “AW2500”×2, available from Tosoh Corporation) under an analytical condition involving: a flow rate of 0.3 mL/min; an elution solvent of a mixture prepared by adding LiBr (30 mM) and citric acid (30 mM) to N,N′-dimethylacetamide; and a column temperature of 40° C., with mono-dispersed polystyrene as a standard.

Average Thickness of Film

The average thickness of the film was measured using a spectroscopic ellipsometer (“A2000D,” available from J.A. Woollam Co.).

Preparation of Mixture (Z)

The compound (M), the compound (X), the solvent (B), and the solvent (C) are shown below. It is to be noted that in the following Synthesis Examples, unless otherwise specified particularly, the term “parts by mass” means a value, provided that a mass of the compound (M) used was 100 parts by mass. Furthermore, “molar ratio” means a value, provided that an amount of substance of the compound (M) used was 1.

The following compounds were used as the compound (M).

M-1: titanium(IV) tetraisopropoxide

M-2: aluminum(III) triisopropoxide

M-3: hafnium(IV) tetraisopropoxide

M-4: tantalum(V) pentaethoxy

M-5: zirconium(IV) tetra-n-butoxide

As the compound (X), compounds (hereinafter, may be also referred to as “compounds (X-1) to (X-10)” and “compound (x-1)”) represented by the following formulae (X-1) to (X-10) and (x-1) were used.

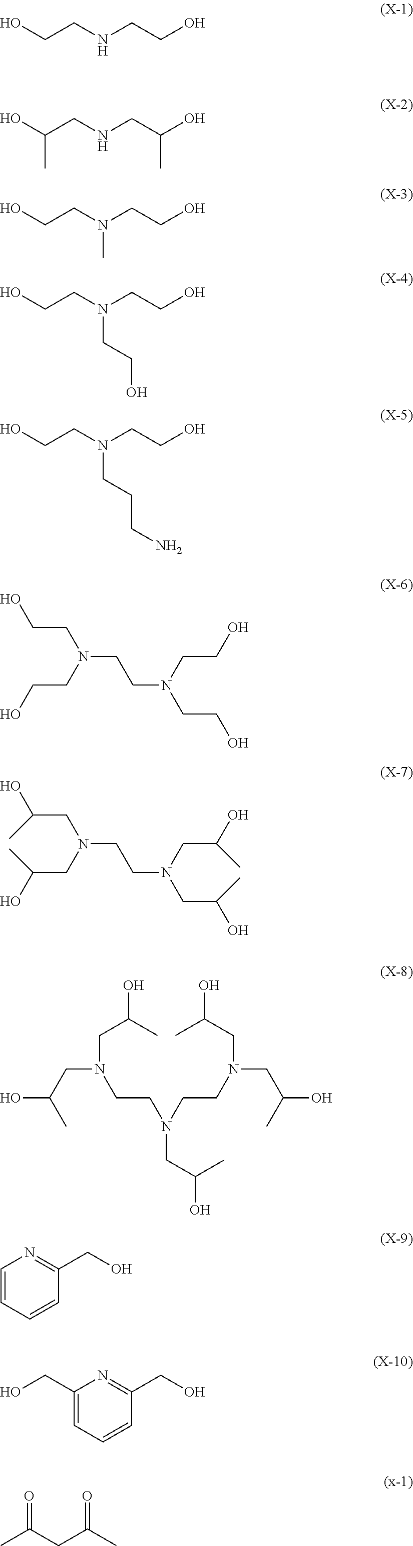

As the solvent (B), the following compounds were used.

B-1: isopropyl alcohol

B-2: ethanol

B-3: 1-butanol

As the solvent (C), the following compounds were used.

C-1: propylene glycol monoethyl ether

C-2: propylene glycol monomethyl ether acetate

C-3: tripropylene glycol

C-4: tripropylene glycol monomethyl ether

C-5: triethylene glycol

C-6: tetraethylene glycol monomethyl ether

### Synthesis Example 1-1: Preparation of Example 1-1 (Compound (Z) (Z-1))

The compound (M-1) was charged into a reaction vessel in an N₂ atmosphere, and the compound (X-1) (molar ratio: 1) was added dropwise over 30 min while stirring at room temperature (25° C. to 30° C.). Next, a reaction was permitted at 60° C. for 2 hrs. After completion of the reaction, the temperature in the reaction vessel was cooled to no greater than 30° C. A thus cooled reaction liquid was diluted with 900 parts by mass of the solvent (B-1). While stirring the thus diluted reaction liquid at room temperature (25° C. to 30° C.), water (molar ratio: 0.75) was added dropwise over 10 min. Next, a hydrolytic condensation reaction was permitted at 60° C. for 2 hrs. After completion of the hydrolytic condensation reaction, the temperature in the reaction vessel was cooled to no greater than 30° C. Into the thus cooled reaction liquid were charged 1,000 parts by mass of the solvent (C-1), and then then elimination of water, the solvent (B-1), alcohol generated by the hydrolytic condensation reaction, and the excess solvent (C-1) by using an evaporator gave the mixture (Z-1). The Mw of the hydrolytic condensation product in the mixture (Z-1) was 1,800. A concentration of components other than the solvent in the mixture (Z-1) was 7.4% by mass.

### Synthesis Examples 1-2 to 1-17: Preparation of Examples 1-2 to 1-17 (Mixture (Z) (Z-2) to (Z-17))

Mixtures (Z-2) to (Z-17) were obtained by a similar operation to that of Synthesis Example 1-1, except that the compound (M), the compound (X), the solvent (B), the amount of water during condensation, and the solvent (C) of the type and in the amount shown in Table 1 below were used. The Mw of the hydrolytic condensation product in the mixture (Z) and the concentration (% by mass) of the components other than the solvent in the mixture (Z) are shown together in Table 1.

### Synthesis Example 1-18: Preparation of Example 1-18 (Mixture (Z) (Z-18))

The compound (M-1) was charged into a reaction vessel in an N₂ atmosphere, and the compound (X-1) (molar ratio: 2) was added dropwise over 30 min while stirring at room temperature (25° C. to 30° C.). Next, a reaction was permitted at 60° C. for 2 hrs. After completion of the reaction, the temperature in the reaction vessel was cooled to no greater than 30° C. A thus cooled reaction liquid was diluted with 330 parts by mass of the solvent (B-1). While stirring the thus diluted reaction liquid at room temperature (25° C. to 30° C.), water (molar ratio: 0.75) was added dropwise over 10 min. Next, a hydrolytic condensation reaction was permitted at 60° C. for 2 hrs. After completion of the hydrolytic condensation reaction, the temperature in the reaction vessel was cooled to no greater than 30° C. Into the thus cooled reaction liquid were charged 430 parts by mass of the solvent (C-1), and then water, the solvent (B-1), alcohol generated by the hydrolytic condensation reaction, and the excess solvent (C-1) were eliminated by using an evaporator to obtain the mixture (Z-18). The Mw of the hydrolytic condensation product in the mixture (Z-18) was 1,400. A concentration of components other than the solvent in the mixture (Z-18) was 32.1% by mass.

### Synthesis Example 1-19: Synthesis of Example 1-19 (Mixture (Z) (Z-19))

The compound (M-1) was charged into a reaction vessel in an N₂ atmosphere, and the compound (X-1) (molar ratio: 2) was added dropwise over 30 min while stirring at room temperature (25° C. to 30° C.). Next, a reaction was permitted at 60° C. for 2 hrs. After completion of the reaction, the temperature in the reaction vessel was cooled to no greater than 30° C. A thus cooled reaction liquid was diluted with 70 parts by mass of the solvent (B-1). While stirring the thus diluted reaction liquid at room temperature (25° C. to 30° C.), water (molar ratio: 0.75) was added dropwise over 10 min. Next, a hydrolytic condensation reaction was permitted at 60° C. for 2 hrs. After completion of the hydrolytic condensation reaction, the temperature in the reaction vessel was cooled to no greater than 30° C. Into the thus cooled reaction liquid were charged 170 parts by mass of the solvent (C-1), and then water, the solvent (B-1), alcohol generated by the hydrolytic condensation reaction, and the excess solvent (C-1) were eliminated by using an evaporator to obtain the mixture (Z-19). The Mw of the hydrolytic condensation product in the mixture (Z-19) was 1,450. A concentration of components other than the solvent in the mixture (Z-19) was 53.2% by mass.

### Synthesis Example 1-20: Preparation of Comparative Example 1-1 (mixture (z) (z-1))

Mixture (z-1) was obtained by a similar operation to that of Synthesis Example 1-1, except that the compound (M), the compound (X), the solvent (B), water, and the solvent (C) of the type and in the amount shown in Table 1 below were used.

### Synthesis Example 1-21: Preparation of Comparative Example 1-2 (Mixture (z) (z-2))

The compound (M-1) was charged into a reaction vessel in an N₂ atmosphere, and the compound (x-1) (molar ratio: 2) was added dropwise over 30 min while stirring at room temperature (25° C. to 30° C.). Next, a reaction was permitted at 60° C. for 2 hrs. After completion of the reaction, the temperature in the reaction vessel was cooled to no greater than 30° C. A thus cooled reaction liquid was diluted with 270 parts by mass of the solvent (B-1). While stirring the thus diluted reaction liquid at room temperature (25° C. to 30° C.), water (molar ratio: 2.0) was added dropwise over 10 min. Next, a hydrolytic condensation reaction was permitted at 60° C. for 2 hrs. After completion of the hydrolytic condensation reaction, the temperature in the reaction vessel was cooled to no greater than 30° C. Into the thus cooled reaction liquid were charged 370 parts by mass of the solvent (C-1), and then water, isopropanol, alcohol generated by the hydrolytic condensation reaction, and the excess solvent (C-1) were eliminated by using an evaporator to obtain the mixture (z-2). The Mw of the hydrolytic condensation product in the mixture (z-2) was 1,650. A concentration of components other than the solvent in the mixture (z-2) was 13.0% by mass.

TABLE 1

| | | | | | | | | | | Concentration of |
|---|---|---|---|---|---|---|---|---|---|---|
| | | | | | | | | | | components other |
| | | | | | | | | | | than solvent |
| | | (M) Compound | | (X) Compound | | (B) Solvent | Water | (C) Solvent | | in mixture (Z) |
| — | (Z) Mixture | type | molar ratio | type | molar ratio | type | molar ratio | type | Mw | (% by mass) |
| Example 1-1 | Z-1 | M-1 | 1 | X-1 | 1 | B-1 | 0.75 | C-1 | 1,800 | 7.4 |
| Example 1-2 | Z-2 | M-1 | 1 | X-1 | 2 | B-1 | 0.75 | C-1 | 1,500 | 7.9 |
| Example 1-3 | Z-3 | M-1 | 1 | X-1 | 5 | B-1 | 0.75 | C-1 | 1,050 | 8.3 |
| Example 1-4 | Z-4 | M-1 | 1 | X-1 | 2 | B-1 | 0.75 | C-2 | 1,500 | 7.9 |
| Example 1-5 | Z-5 | M-1 | 1 | X-2 | 2 | B-1 | 0.75 | C-1 | 1,750 | 8.2 |
| Example 1-6 | Z-6 | M-1 | 1 | X-3 | 2 | B-1 | 1.5 | C-1 | 1,900 | 8.0 |
| Example 1-7 | Z-7 | M-1 | 1 | X-4 | 2 | B-1 | 3 | C-1 | 1,200 | 8.7 |
| Example 1-8 | Z-8 | M-1 | 1 | X-5 | 2 | B-1 | 1.5 | C-1 | 1,450 | 7.4 |
| Example 1-9 | Z-9 | M-1 | 1 | X-6 | 0.5 | B-1 | 3 | C-1 | 1,050 | 8.8 |
| Example 1-10 | Z-10 | M-1 | 1 | X-7 | 0.5 | B-1 | 4.5 | C-1 | 1,100 | 8.7 |
| Example 1-11 | Z-11 | M-1 | 1 | X-8 | 0.4 | B-1 | 1.5 | C-1 | 950 | 9.0 |
| Example 1-12 | Z-12 | M-1 | 1 | X-9 | 2 | B-1 | 1.5 | C-1 | 1,950 | 7.4 |
| Example 1-13 | Z-13 | M-1 | 1 | X-10 | 1 | B-1 | 1.5 | C-1 | 1,500 | 7.7 |
| Example 1-14 | Z-14 | M-2 | 1 | X-1 | 2 | B-1 | 0.75 | C-1 | 1,600 | 7.5 |
| Example 1-15 | Z-15 | M-3 | 1 | X-1 | 2 | B-1 | 0.75 | C-1 | 2,100 | 7.4 |
| Example 1-16 | Z-16 | M-4 | 1 | X-1 | 2 | B-2 | 0.75 | C-1 | 2,000 | 7.7 |
| Example 1-17 | Z-17 | M-5 | 1 | X-1 | 2 | B-3 | 0.75 | C-1 | 1,800 | 7.6 |
| Example 1-18 | Z-18 | M-1 | 1 | X-1 | 2 | B-1 | 0.75 | C-1 | 1,400 | 32.1 |
| Example 1-19 | Z-19 | M-1 | 1 | X-1 | 2 | B-1 | 0.75 | C-1 | 1,450 | 53.2 |
| Comparative | z-1 | M-1 | 1 | x-1 | 2 | B-1 | 2 | C-1 | 1,600 | 7.0 |
| Example 1-1 | | | | | | | | | | |
| Comparative | z-2 | M-1 | 1 | x-1 | 2 | B-1 | 2 | C-1 | 1,650 | 13.0 |
| Example 1-2 | | | | | | | | | | |

### Film-Forming Composition Preparation (1)

### Example 2-1: Preparation of Film-Forming Composition (J-1)

As shown in Table 2 below, (Z-1) as the mixture (Z) and (C-1) as the solvent (C) were mixed such that a content of the solvent (C) with respect to 4 parts by mass of components other than the solvent in the mixture (Z) was 96 parts by mass (including the solvent (C) contained in the mixture (Z)). The solution thus obtained was filtered through a filter having a pore size of 0.2 μm to prepare the film-forming composition (J-1).

### Examples 2-2 to 2-17: Preparation of Film-Forming Compositions (J-2) to (J-17)

Each of film-forming compositions (J-2) to (J-17) was prepared by a similar operation to that of Example 2-1, except that the type and content of each component were as shown in Table 2 below.

### Comparative Example 2-1: Preparation of Film-Forming Composition (j-1)

Film-forming composition (j-1) was prepared by a similar operation to that of Example 2-1, except that the type and content of each component were as shown in Table 2 below.

TABLE 2

| | | Components other than | | | |
|---|---|---|---|---|---|
| | | solvent in mixture (Z) | | (C) Solvent | |
| | Film- | type of | content | | content |
| | forming | mixture | (parts | | (parts |
| — | composition | (Z) | by mass) | type | by mass) |
| Example 2-1 | J-1 | Z-1 | 4 | C-1 | 96 |
| Example 2-2 | J-2 | Z-2 | 4 | C-1 | 96 |
| Example 2-3 | J-3 | Z-3 | 4 | C-1 | 96 |
| Example 2-4 | J-4 | Z-4 | 4 | C-2 | 96 |
| Example 2-5 | J-5 | Z-5 | 4 | C-1 | 96 |
| Example 2-6 | J-6 | Z-6 | 4 | C-1 | 96 |
| Example 2-7 | J-7 | Z-7 | 4 | C-1 | 96 |
| Example 2-8 | J-8 | Z-8 | 4 | C-1 | 96 |
| Example 2-9 | J-9 | Z-9 | 4 | C-1 | 96 |
| Example 2-10 | J-10 | Z-10 | 4 | C-1 | 96 |
| Example 2-11 | J-11 | Z-11 | 4 | C-1 | 96 |
| Example 2-12 | J-12 | Z-12 | 4 | C-1 | 96 |
| Example 2-13 | J-13 | Z-13 | 4 | C-1 | 96 |
| Example 2-14 | J-14 | Z-14 | 4 | C-1 | 96 |
| Example 2-15 | J-15 | Z-15 | 4 | C-1 | 96 |
| Example 2-16 | J-16 | Z-16 | 4 | C-1 | 96 |
| Example 2-17 | J-17 | Z-17 | 4 | C-1 | 96 |
| Comparative | j-1 | z-1 | 4 | C-1 | 96 |
| Example 2-1 | | | | | |

### Comparative Example 2-2: Preparation of Film-Forming Composition (j-2)

1.61 g of oxalic acid was dissolved in 96.45 g of water with heating to prepare an aqueous oxalic acid solution. Thereafter, a flask charged with 25.70 g (70 mol %) of tetramethoxysilane, 9.86 g (30 mol %) of methyltrimethoxysilane, and 366.39 g of propylene glycol monoethyl ether was fitted with a cooling tube and a dropping funnel containing the aqueous oxalic acid solution thus prepared. Next, after heating the mixture to 60° C. using an oil bath, the aqueous oxalic acid solution was slowly added dropwise to the mixture, and a reaction of the mixture was permitted at 60° C. for 4 hours. After completion of the reaction, the flask containing the reaction solution was allowed to cool, and then fitted with an evaporator. The reaction solution was then concentrated in vacuo to give 360 g of a polysiloxane solution. A concentration of components other than the solvent in the polysiloxane solution thus obtained was 9.8% by mass. The weight average molecular weight (Mw) of the polysiloxane thus obtained was 1,500. The polysiloxane solution was mixed with propylene glycol monoethyl ether to adjust the concentration of the components other than the solvent in the polysiloxane solution to be 4% by mass, thereby preparing the film-forming composition (j-2).

### Evaluations

In accordance with the following procedures, each of the film-forming compositions prepared as above was evaluated on storage stability, the film-thickness-variation-inhibiting property, oxygen-based gas etching resistance, the embedding property, and removability. The evaluation results are shown in Table 3 below.

Storage Stability

Each of the film-forming compositions was evaluated on storage stability by a change in coating characteristics due to a passage of time. Each of the film-forming compositions directly after preparation as described above (T=0) was applied on a silicon wafer (substrate) with a spin coater (“CLEAN TRACK ACT 8,” available from Tokyo Electron Limited) by way of a spin-coating procedure under a condition involving 1,500 rpm and 30 sec, followed by heating a thus resulting coating film at 90° C. for 60 sec to form a metal-containing film. With regard to the coating characteristics, each of the metal-containing films thus formed was observed with an optical microscope, and evaluated to be: “A” (favorable) in a case of finding no coating unevenness; and “B” (unfavorable)” in a case of finding coating unevenness. Furthermore, each composition, having been evaluated on the coating characteristics, was stored at 20° C. for 60 days (T=60) and then similarly subjected to a coating characteristics evaluation, and evaluated similarly. The storage stability can be evaluated to be: favorable in a case in which both the coating characteristics at T=0 and the coating characteristics at T=60 are “A” (favorable); and unfavorable in a case in which at least one of the coating characteristics is not “A.”

Film-Thickness-Variation-Inhibiting Property

A metal-containing film was formed by: applying the film-forming composition prepared as described above on an 8-inch silicon wafer with the spin coater by way of a spin-coating procedure under a condition involving 1,500 rpm and 30 sec, followed by heating at 250° C. for 60 sec after passage of a predetermined time period and cooling at 23° C. for 30 sec. As the metal-containing film, each of a “metal-containing film (a0),” in a case in which the predetermined time period was 30 sec, and a “metal-containing film (a1),” in a case in which the predetermined time period was 300 sec, was formed; an average thickness of the metal-containing film (a0) was considered to be T0 and an average thickness of the metal-containing film (a1) was considered to be T1, and a film-thickness-variation percentage (%) was determined by the following formula, being used as a marker for the film-thickness-variation-inhibiting property.

Film-thickness-variation percentage (%)=|T1−T0|×100/T0

The film-thickness-variation-inhibiting property was evaluated to be: “A” (favorable) in a case in which the film-thickness-variation percentage was less than 1.7%; and “B” (unfavorable) in a case in which the film-thickness-variation-inhibiting percentage was no less than 1.7%.

Oxygen-Based Gas Etching Resistance

A metal-containing film having an average thickness of 100 nm was formed by: applying the film-forming composition prepared as described above on an 8-inch silicon wafer with the spin coater by way of a spin-coating procedure, followed by heating at 220° C. for 60 sec and cooling at 23° C. for 30 sec.

The substrate on which the metal-containing film was formed was subjected to an etching treatment by using an etching apparatus (“Tactras-Vigus” available from Tokyo Electron Limited), under conditions involving O₂=400 sccm, PRESS.=25 mT, HF RF (radiofrequency power for plasma production)=200 W, LF RF (radiofrequency power for bias)=0 W, DCS=0 V, RDC (flow rate percentage at gas center)=50%, for 60 sec. An etching rate (nm/min) was calculated based on the average film thickness of the silicon-containing film before the treatment and the average film thickness of the silicon-containing film after the treatment, and the resistance to etching by oxygen-based gas was evaluated. The etching resistance was evaluated to be: “A” (favorable) in a case in which the etching rate was less than 1.0 nm/min; and “B” (unfavorable) in a case in which the etching rate was no less than 1.0 nm/min.

Embedding Property

On a silicon nitride substrate having a trench pattern with a depth of 300 nm and a width of 30 nm formed thereon, the film-forming composition prepared as described above was applied with the spin coater by way of a spin-coating procedure using an organic underlayer-forming material (“HM8006,” available from JSR Corporation). A rotational speed for the spin coating was the same as that in the case of forming the film having the average thickness of 100 nm on the silicon wafer in the evaluation of the “Oxygen-Based Gas Etching Resistance,” described above. Next, heating was carried out in an ambient atmosphere at 250° C. for 60 sec, followed by cooling at 23° C. for 30 sec to obtain the substrate having a metal-containing film formed thereon. The presence/absence of an embedding defect (void) was confirmed on a cross-section of the substrate thus obtained by using a field emission scanning electron microscope (“S-4800,” available from Hitachi High-Technologies Corporation). The embedding property was evaluated to be: “A” (favorable) in a case of no embedding defect being observed; and “B” (unfavorable) in a case of the defect being observed.

Removability

Formation of Metal-Containing-Film-Attached Substrate

A metal-containing-film-attached substrate, being a substrate having a metal-containing film formed on a surface thereof, was made by: applying the film-forming composition prepared as described above on an 8-inch silicon wafer with the spin coater by way of a spin-coating procedure, followed by heating at 220° C. for 60 sec and cooling at 23° C. for 30 sec to form the metal-containing film with an average thickness of 100 nm.

Removal of Metal-Containing Film

Each metal-containing-film-attached substrate made as described above was processed by film-removing conditions described below. The surface of each metal-containing-film-attached substrate was brought into contact with a removing liquid indicated in Table 3 below by way of a puddle procedure, and then dried by spinning with the spin coater.

Film Removal Condition 1

Each metal-containing-film-attached substrate obtained as described above was immersed for 5 min in a removing liquid (R-1) (mixed aqueous solution; 25% by mass aqueous ammonia solution/30% by mass hydrogen peroxide solution/water=1/1/5 (volume ratio)) having been heated to 65° C.

Film Removal Condition 2

Each metal-containing-film-attached substrate obtained as described above was immersed for 5 min in a removing liquid (R-2) (mixed aqueous solution; 96% by mass sulfuric acid/30% by mass hydrogen peroxide solution=3/1 (volume ratio)) having been heated to 50° C.

Film Removal Condition 3

Each metal-containing-film-attached substrate obtained as described above was immersed for 5 min in a removing liquid (R-3) (85% by mass aqueous phosphoric acid solution) having been heated to 50° C.

Evaluations

Each metal-containing film was evaluated on removability by the following procedure.

Each metal-containing-film-attached substrate thus obtained was observed with cross-sectional SEM, and was evaluated to be: “A” (favorable) in a case in which the metal-containing film did not remain; and “B” (unfavorable) in a case in which the metal-containing film remained.

TABLE 3

| | | | | Film-thickness- | | Oxygen-based | Removability | | |
|---|---|---|---|---|---|---|---|---|---|
| | Film-forming | Storage stability | | variation-inhibiting | Embedding | gas etching | removing | removing | removing |
| — | composition | T = 0 | T = 60 | property | property | resistance | liquid R-1 | liquid R-2 | liquid R-3 |
| Example 2-1 | J-1 | A | A | A | A | A | A | A | A |
| Example 2-2 | J-2 | A | A | A | A | A | A | A | A |
| Example 2-3 | J-3 | A | A | A | A | A | A | A | A |
| Example 2-4 | J-4 | A | A | A | A | A | A | A | A |
| Example 2-5 | J-5 | A | A | A | A | A | A | A | A |
| Example 2-6 | J-6 | A | A | A | A | A | A | A | A |
| Example 2-7 | J-7 | A | A | A | A | A | A | A | A |
| Example 2-8 | J-8 | A | A | A | A | A | A | A | A |
| Example 2-9 | J-9 | A | A | A | A | A | A | A | A |
| Example 2-10 | J-10 | A | A | A | A | A | A | A | A |
| Example 2-11 | J-11 | A | A | A | A | A | A | A | A |
| Example 2-12 | J-12 | A | A | A | A | A | A | A | A |
| Example 2-13 | J-13 | A | A | A | A | A | A | A | A |
| Example 2-14 | J-14 | A | A | A | A | A | A | A | A |
| Example 2-15 | J-15 | A | A | A | A | A | A | A | A |
| Example 2-16 | J-16 | A | A | A | A | A | A | A | A |
| Example 2-17 | J-17 | A | A | A | A | A | A | A | A |
| Comparative | j-1 | A | B | B | B | A | A | A | A |
| Example 2-1 | | | | | | | | | |
| Comparative | j-2 | A | A | A | A | B | B | B | B |
| Example 2-2 | | | | | | | | | |

As is seen from the results shown in Table 3 above, the film-forming compositions of the Examples are superior in the storage stability and the embedding property. Furthermore, as is seen from the results shown in Table 3 above, the films formed from the film-forming compositions of the Examples are superior in the film-thickness-variation-inhibiting property, oxygen-based gas etching resistance, and removability.

### Preparation of Film-Forming Composition (2)

As the other optional component, the following compounds were used.

D-1: surfactant (“NBX-15,” available from NEOS COMPANY LIMITED)

D-2: surfactant (“F563,” available from DIC Corporation)

D-3: poly(2-ethylhexylacrylate)

### Example 3-1: Preparation of Film-Forming Composition (J-18)

As shown in Table 4 below, (Z-18) as the mixture (Z) and (C-1) as the solvent (C) were mixed such that a content of the solvent (C) with respect to 4 parts by mass of components other than the solvent in the mixture (Z) was 96 parts by mass (including the solvent (C) contained in the mixture (Z)). The solution thus obtained was filtered through a filter having a pore size of 0.2 μm to prepare the film-forming composition (J-18).

### Examples 3-2 to 3-21: Preparation of Film-Forming Compositions (J-19) to (J-38)

Each of film-forming compositions (J-19) to (J-38) was prepared by a similar operation to that of Example 3-1, except that the type and content of each component were as shown in Table 4 below.

### Comparative Examples 3-1 and 3-2: Preparation of Film-Forming Compositions (j-3) and (j-4)

Each of film-forming compositions (j-3) and (j-4) was prepared by a similar operation to that of Example 3-1, except that the type and content of each component were as shown in Table 4 below.

TABLE 4

| | | Components other than | | | | | |
|---|---|---|---|---|---|---|---|
| | | solvent in mixture (Z) | | (C) Mixture | | Other optional component | |
| | Film-forming | type of | content (parts | | content (parts | | content (parts |
| — | composition | mixture (Z) | by mass) | type | by mass) | type | by mass) |
| Example 3-1 | J-18 | Z-18 | 4 | C-1 | 96 | — | — |
| Example 3-2 | J-19 | Z-18 | 6 | C-1 | 96 | — | — |
| Example 3-3 | J-20 | Z-18 | 10 | C-1 | 90 | D-1 | 0.05 |
| Example 3-4 | J-21 | Z-18 | 20 | C-1 | 80 | D-1 | 0.05 |
| Example 3-5 | J-22 | Z-18 | 20 | C-1 | 80 | D-1 | 0.005 |
| Example 3-6 | J-23 | Z-18 | 20 | C-1 | 80 | D-1 | 0.001 |
| Example 3-7 | J-24 | Z-18 | 20 | C-1 | 80 | D-1 | 0.1 |
| Example 3-8 | J-25 | Z-18 | 20 | C-1 | 80 | D-1 | 1 |
| Example 3-9 | J-26 | Z-18 | 20 | C-1 | 80 | D-1 | 3 |
| Example 3-10 | J-27 | Z-18 | 30 | C-1 | 70 | D-1 | 0.05 |
| Example 3-11 | J-28 | Z-19 | 40 | C-1 | 60 | D-1 | 0.05 |
| Example 3-12 | J-29 | Z-19 | 50 | C-1 | 50 | D-1 | 0.05 |
| Example 3-13 | J-30 | Z-19 | 53 | C-1 | 47 | D-1 | 0.05 |
| Example 3-14 | J-31 | Z-19 | 53 | C-1/C-3 | 42/5 | D-1 | 0.05 |
| Example 3-15 | J-32 | Z-19 | 53 | C-1/C-4 | 42/5 | D-1 | 0.05 |
| Example 3-16 | J-33 | Z-19 | 53 | C-1/C-5 | 42/5 | D-1 | 0.05 |
| Example 3-17 | J-34 | Z-19 | 53 | C-1/C-6 | 42/5 | D-1 | 0.05 |
| Example 3-18 | J-35 | Z-18 | 20 | C-1 | 80 | D-2 | 0.05 |
| Example 3-19 | J-36 | Z-19 | 50 | C-1 | 50 | D-2 | 0.05 |
| Example 3-20 | J-37 | Z-19 | 53 | C-1 | 47 | D-2 | 0.05 |
| Example 3-21 | J-38 | Z-19 | 20 | C-1 | 80 | D-3 | 0.05 |
| Comparative | j-3 | z-2 | 10 | C-1 | 90 | — | — |
| Example 3-1 | | | | | | | |
| Comparative | j-4 | z-2 | 10 | C-1 | 90 | D-1 | 0.05 |
| Example 3-2 | | | | | | | |

Evaluations

Each film-forming composition prepared as described above was evaluated by the following procedures on coating characteristics and the generation of cracks. The results of the evaluations are shown in Table 4 below.

Coating Characteristics

Metal-containing films (Examples 3-1 to 3-26 and Comparative Examples 3-1 and 3-2) shown in Table 4 below were formed by: applying each of the film-forming compositions prepared as described above on an 8-inch silicon wafer with the spin coater by way of a spin-coating procedure, followed by heating under conditions involving the temperature (° C.) and the time period (sec) shown in Table 4 below, and cooling at 23° C. for 30 sec. With respect to the metal-containing film, the presence/absence of a streak defect (striation) from a center toward a circumferential direction was visually observed. The coating characteristics were evaluated to be: “A” (favorable) in the case of no streak defect being present; and “B” (unfavorable) in the case of the streak defect being present.

Generation of Cracks

Metal-containing films (Examples 3-1 to 3-26 and Comparative Examples 3-1 and 3-2) shown in Table 4 below were formed by: applying each of the film-forming compositions prepared as described above on the 8-inch silicon wafer with the spin coater by way of the spin-coating procedure, followed by heating under conditions involving the temperature (° C.) and the time period (sec) shown in Table 4 below, and cooling at 23° C. for 30 sec. Furthermore, with regard to each of Examples 3-25 and 3-26, the metal-containing film was exposed to UV in clean air for 10 min. With regard to a light source of the UV, an Xe excimer lamp (wavelength: 172 nm, 10 mW/cm²; available from Ushio, Inc.) was used. A surface of the metal-containing film formed was observed with the optical microscope. The generation of cracks was evaluated to be: “A” (favorable) in a case in which cracking or peeling of the metal-containing film was not found; and “B” (unfavorable) in a case in which cracking or peeling of the metal-containing film was found.

TABLE 5

| | | Heating conditions | Post-heating | | |
|---|---|---|---|---|---|
| | Film-forming | (temperature/ | film thickness | Coating | Crack |
| — | composition | time period) | (nm) | characteristics | generation |
| Example 3-1 | J-18 | 400° C./60 sec | 70 | A | A |
| Example 3-2 | J-19 | 400° C./60 sec | 110 | A | A |
| Example 3-3 | J-20 | 400° C./60 sec | 200 | A | A |
| Example 3-4 | J-21 | 400° C./60 sec | 450 | A | A |
| Example 3-5 | J-22 | 400° C./60 sec | 450 | A | A |
| Example 3-6 | J-23 | 400° C./60 sec | 450 | A | A |
| Example 3-7 | J-24 | 400° C./60 sec | 450 | A | A |
| Example 3-8 | J-25 | 400° C./60 sec | 450 | A | A |
| Example 3-9 | J-26 | 400° C./60 sec | 450 | A | A |
| Example 3-10 | J-27 | 400° C./60 sec | 1500 | A | A |
| Example 3-11 | J-28 | 400° C./60 sec | 2500 | A | A |
| Example 3-12 | J-29 | 400° C./60 sec | 3500 | A | A |
| Example 3-13 | J-30 | 400° C./60 sec | 3800 | A | A |
| Example 3-14 | J-31 | 400° C./60 sec | 3800 | A | A |
| Example 3-15 | J-32 | 400° C./60 sec | 3800 | A | A |
| Example 3-16 | J-33 | 400° C./60 sec | 3800 | A | A |
| Example 3-17 | J-34 | 400° C./60 sec | 3800 | A | A |
| Example 3-18 | J-35 | 400° C./60 sec | 450 | A | A |
| Example 3-19 | J-36 | 400° C./60 sec | 3,500 | A | A |
| Example 3-20 | J-37 | 400° C./60 sec | 3,800 | A | A |
| Example 3-21 | J-38 | 400° C./60 sec | 450 | A | A |
| Example 3-22 | J-21 | 450° C./60 sec | 310 | — | A |
| Example 3-23 | J-21 | 500° C./60 sec | 190 | — | A |
| Example 3-24 | J-21 | 600° C./60 sec | 190 | — | A |
| Example 3-25 | J-21 | 400° C./60 sec | 380 | — | A |
| Example 3-26 | J-21 | 450° C./60 sec | 260 | — | A |
| Comparative | j-3 | 400° C./60 sec | 200 | B | B |
| Example 3-1 | | | | | |
| Comparative | j-4 | 400° C./60 sec | 200 | A | B |
| Example 3-2 | | | | | |

As is seen from the results shown in Table 5 above, the film-forming compositions of the Examples are superior in coating characteristics, and the films formed therefrom enable inhibiting the generation of cracks. Furthermore, as is seen from the results shown in Table 5 above, the film-forming compositions of the Examples enable inhibiting the generation of cracks, even in the case of forming the thick film.

The film-forming composition of the one embodiment of the present invention is superior in storage stability and the embedding property. Furthermore, the film formed from the film-forming composition of the one embodiment of the present invention is superior in the film-thickness-variation-inhibiting property, etching resistance, and removability. Since the resist underlayer film of the other embodiment of the present invention is formed from the film-forming composition of the one embodiment of the present invention, superiority is achieved in the film-thickness-variation-inhibiting property, etching resistance, and removability. Since the method of forming a film of the still another embodiment of the present invention uses the film-forming composition of the one embodiment of the present invention, a film being superior in each of the film-thickness-variation-inhibiting property, etching resistance, and removability can be formed. Since the method of forming a resist pattern of the still another embodiment of the present invention uses the film-forming composition of the one embodiment of the present invention, a favorable resist pattern can be formed. Since the method of forming an organic-underlayer-film reverse pattern of the further embodiment of the present invention uses the film-forming composition of the one embodiment of the present invention as the organic-underlayer-film-reverse-pattern-forming composition, a favorable reverse pattern can be formed. The method of producing a film-forming composition of the yet further embodiment of the present invention enables producing a film-forming composition being superior in storage stability and the embedding property, as well as in etching resistance, the film-thickness-variation-inhibiting property, and removability.

Since the method of forming a metal-containing film pattern of the still further embodiment of the present invention uses the film-forming composition of the one embodiment of the present invention as the metal-containing-film-forming composition, a favorable metal-containing film pattern can be formed.

The film-forming composition of the one embodiment of the present invention is superior in coating characteristics when forming a thick film. Moreover, the film-forming composition of the one embodiment of the present invention enables forming a thick film in which the generation of cracks is inhibited.

Furthermore, since the method of forming a metal-containing film pattern of the still further embodiment of the present invention uses the film-forming composition of the one embodiment of the present invention as the metal-containing-film-forming composition, a thick film in which the generation of cracks is inhibited can be formed, thereby enabling forming a favorable metal-containing film pattern.

Thus, these can be suitably used in lithography steps in the manufacturing of various types of electronic devices such as semiconductor devices and liquid crystal devices, for which further microfabrication is demanded.

Obviously, numerous modifications and variations of the present invention are possible in light of the above teachings. It is therefore to be understood that within the scope of the appended claims, the invention may be practiced otherwise than as specifically described herein.

What is claimed is:

1. A film-forming composition comprising:
a metal compound;
a nitrogen-containing organic compound; and
a solvent, wherein
the nitrogen-containing organic compound is: a first compound comprising a nitrogen atom, an aliphatic hydrocarbon group, and at least two hydroxy groups; a second compound comprising a nitrogen-containing aromatic heterocycle and at least one hydroxy group; or a mixture thereof.

2. The film-forming composition according to claim 1, wherein the nitrogen-containing organic compound is coordinated to a metal atom in the metal compound, or is free from a metal atom in the metal compound.

3. The film-forming composition according to claim 1, wherein the first compound is represented by formula (1): 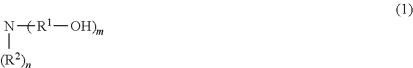
wherein, in the formula (1), (m+n) is 3, m is 2 or 3, and n is 0 or 1; R¹ represents a divalent aliphatic hydrocarbon group having 1 to 10 carbon atoms, wherein a plurality of R¹s are identical or different from each other; and R² represents a hydrogen atom, a monovalent aliphatic hydrocarbon group having 1 to 10 carbon atoms, or a group represented by formula (1-1): 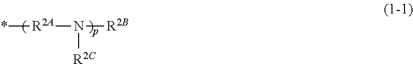
wherein, in the formula (1-1), R^{2A} represents a divalent aliphatic hydrocarbon group having 1 to 10 carbon atoms; R^{2B} and R^{1C} each independently represent a hydrogen atom, a monovalent aliphatic hydrocarbon group having 1 to 10 carbon atoms, or —R^{2D}—OH, wherein R^{2D} represents a divalent aliphatic hydrocarbon group having 1 to 10 carbon atoms; p is an integer of 1 to 4, wherein in a case in which p is no less than 2, a plurality of R^{2A}s are identical or different from each other, and a plurality of R^{2C}s are identical or different from each other; and * denotes a site bonding to the nitrogen atom in the formula (1).

4. The film-forming composition according to claim 1, wherein the second compound comprises:
at least one divalent aliphatic hydrocarbon group having 1 to 10 carbon atoms bonded to the nitrogen-containing aromatic heterocycle; and
at least one hydroxy group bonded to each of the at least one divalent aliphatic hydrocarbon group.

5. The film-forming composition according to claim 1, wherein a metal atom in the metal compound belongs to period 3 to period 7 of group 2 to group 14 in periodic table.

6. The film-forming composition according to claim 5, wherein the metal atom belongs to group 4 in the periodic table.

7. The film-forming composition according to claim 1, which is suitable for forming a resist underlayer film.

8. The film-forming composition according to claim 1, which is suitable for forming an organic-underlayer-film reverse pattern.

9. A resist underlayer film formed from the film-forming composition according to claim 1.

10. A method of forming a film, the method comprising applying the film-forming composition according to claim 1 directly or indirectly on a substrate.

11. A method of forming a resist pattern, the method comprising:
applying the film-forming composition according to claim 1 directly or indirectly on a substrate to form a resist underlayer film;
applying an organic-resist-film-forming composition directly or indirectly on the resist underlayer film to form an organic resist film;
exposing the organic resist film to a radioactive ray; and
developing the organic resist film exposed.

12. The method according to claim 11, wherein the nitrogen-containing organic compound is coordinated to a metal atom in the metal compound, or is free from a metal atom in the metal compound.

13. The method according to claim 11, wherein the nitrogen-containing organic compound comprises the first compound represented by formula (1): 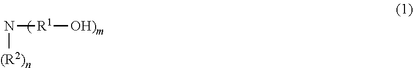
wherein, in the formula (1), (m+n) is 3, m is 2 or 3, and n is 0 or 1; R¹ represents a divalent aliphatic hydrocarbon group having 1 to 10 carbon atoms, wherein a plurality of R¹s are identical or different from each other; and R² represents a hydrogen atom, a monovalent aliphatic hydrocarbon group having 1 to 10 carbon atoms, or a group represented by formula (1-1): 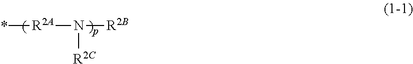
wherein, in the formula (1-1), R^{2A} represents a divalent aliphatic hydrocarbon group having 1 to 10 carbon atoms; R^{2B} and R^{1C} each independently represent a hydrogen atom, a monovalent aliphatic hydrocarbon group having 1 to 10 carbon atoms, or —R^{2D}—OH, wherein R^{2D} represents a divalent aliphatic hydrocarbon group having 1 to 10 carbon atoms; p is an integer of 1 to 4, wherein in a case in which p is no less than 2, a plurality of R^{2A}s are identical or different from each other, and a plurality of R^{2C}s are identical or different from each other; and * denotes a site bonding to the nitrogen atom in the formula (1).

14. The method according to claim 11, wherein the nitrogen-containing organic compound comprises a second compound comprising:
at least one divalent aliphatic hydrocarbon group having 1 to 10 carbon atoms bonded to the nitrogen-containing aromatic heterocycle; and
at least one hydroxy group bonded to each of the at least one divalent aliphatic hydrocarbon group.

15. The method according to claim 11, wherein a metal atom in the metal compound belongs to period 3 to period 7 of group 2 to group 14 in periodic table.

16. The method according to claim 15, wherein the metal atom belongs to group 4 in the periodic table.

17. A method of forming an organic-underlayer-film reverse pattern, the method comprising:
forming an organic underlayer film directly or indirectly on a substrate;
forming a resist pattern directly or indirectly on the organic underlayer film;
forming an organic-underlayer-film pattern on the organic underlayer film by carrying out etching using the resist pattern as a mask;
forming an organic-underlayer-film-reverse-pattern-forming film directly on the organic-underlayer-film pattern by applying an organic-underlayer-film-reverse-pattern-forming composition; and
forming an organic-underlayer-film reverse pattern by removing the organic-underlayer-film pattern, wherein
the organic-underlayer-film-reverse-pattern-forming composition comprises:
a metal compound;
a nitrogen-containing organic compound; and
a solvent, wherein
the nitrogen-containing organic compound is: a first compound comprising a nitrogen atom, an aliphatic hydrocarbon group, and at least two hydroxy groups; a second compound comprising a nitrogen-containing aromatic heterocycle and at least one hydroxy group; or a mixture thereof.

18. A method of producing a film-forming composition, the method comprising:
mixing a metal alkoxide with a nitrogen-containing organic compound to obtain a mixture; and
adding water to the mixture, wherein
the nitrogen-containing organic compound is: a first compound comprising a nitrogen atom, an aliphatic hydrocarbon group, and at least two hydroxy groups; a second compound comprising a nitrogen-containing aromatic heterocycle and at least one hydroxy group; or a mixture thereof.

19. A method of forming a metal-containing film pattern, the method comprising:
applying a metal-containing-film-forming composition directly or indirectly on a substrate;
forming an organic underlayer film directly or indirectly on a metal-containing film formed by applying the metal-containing-film-forming composition;
forming a resist pattern directly or indirectly on the organic underlayer film; and
forming a pattern on the metal-containing film by carrying out etching using the resist pattern as a mask, wherein
the metal-containing-film-forming composition is the film-forming composition according to claim 1.
